(19) United States
(12) Patent Application Publication
(10) Pub. No.: US 2026/0338330 A1
(43) Pub. Date: Oct. 29, 2026

(54) SYSTEM AND METHOD FOR SUSTAINABILITY, EVALUATION, DESIGN, AND OPTIMIZATION OF NATURAL GAS TRANSMISSION NETWORK OPERATIONS

(71) Applicant: SAUDI ARABIAN OIL COMPANY, Dhahran (SA)

(72) Inventor: Diego Armando Moya-Pinta, Ambato (EC)

(73) Assignee: SAUDI ARABIAN OIL COMPANY, Dhahran (SA)

(21) Appl. No.: 19/192,839

(22) Filed: Apr. 29, 2025

(51) Int. Cl. F17D 5/00; G06F 30/18

(52) U.S. Cl. CPC F17D 5/005; G06F 30/18

(57) ABSTRACT

Method for evaluating the sustainability of a gas transmission network, for example, in terms of energy consumption and emissions. The gas transmission network including at least one gas transmission pipeline. The method includes determining geospatial data for the gas transmission network, the gas transmission network represented using a plurality of nodes and at least one segment. The method further includes obtaining an ambient temperature and inlet conditions of a gas conveyed by the gas transmission network. The method further includes simulating the gas transmission network with a physics-based model forming a simulated network. The method further includes determining a location and energy requirement for each of at least one compressor station as part of the gas transmission network based on the geospatial data and simulated network and determining an energy consumption of the gas transmission network based on the energy requirement of each of the at least one compressor station.

### BACKGROUND

Energy, in the form of natural gas, can be transported to one or more customers such as a local distributor using gas transmission pipelines. One or more gas transmission pipelines can be connected to form a network.

It may be beneficial for a producer and/or supplier of natural gas to estimate operational costs, energy consumption, and carbon intensity associated with transporting natural gas using a gas transmission network. For example, accurate estimations of operational costs, energy consumption, emissions, and carbon intensity of gas transmission network operations is important to ensure effective energy and emissions management. Further, such estimates are needed to design, construct, and update gas transmission networks in view of goals related to climate change mitigation and energy infrastructure optimization.

However, estimating these quantities for any given gas transmission network is a difficult task. Despite the increasing use of natural gas globally for energy, there are no platforms that effectively integrate climate conditions, geospatial data including elevation, thermodynamics, and fluid mechanics to determine quantities such as energy consumption and carbon intensity emission.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

Embodiments disclosed herein generally relate to a method for evaluating a gas transmission network. The method includes determining geospatial data for the gas transmission network that includes at least one gas transmission pipeline, where the at least one gas transmission pipeline is represented using a plurality of nodes and at least one segment and the geospatial data includes a longitude, a latitude, and an elevation for each node of the plurality of nodes. The method further includes obtaining, for the gas transmission network, an ambient temperature, and inlet conditions including a temperature, pressure, and flow rate of a gas conveyed by the gas transmission network. The method further includes simulating the gas transmission network with a physics-based model forming a simulated network. The simulation includes: determining a length of each segment of the at least one segment using the geospatial data; determining a change in elevation between each node of the plurality of nodes using the geospatial data; and determining a temperature and pressure of the gas at each of the plurality of nodes based, at least in part, on the length and change in elevation of each of the at least one segments and a spatial relationship of the plurality of nodes. The method further includes determining a location and energy requirement for each of at least one compressor as part of the gas transmission network based on the geospatial data and simulated network and determining an energy consumption of the gas transmission network based on the energy requirement of each of the at least one compressor.

Embodiments disclosed herein generally relate to a gas transmission energy management system. The system includes a gas transmission network with at least one gas transmission pipeline. The system further includes a computer with at least one computer processor. The computer is configured to determine geospatial data for the gas transmission network, where the geospatial data represents the gas transmission network with a plurality of nodes and at least one segment and the geospatial data includes a longitude, a latitude, and an elevation for each node of the plurality of nodes. The computer is further configured to obtain, for the gas transmission network, an ambient temperature, and inlet conditions including a temperature, pressure, and flow rate of a gas conveyed by the gas transmission network. The computer is further configured to simulate the gas transmission network with a physics-based model forming a simulated network. The simulation includes the steps: determining a length of each segment of the at least one segment using the geospatial data; determining a change in elevation between each node of the plurality of nodes using the geospatial data; and determining a temperature and pressure of the gas at each of the plurality of nodes based, at least in part, on the length and change in elevation of each of the at least one segments and a spatial relationship of the plurality of nodes. The computer is further configured to determine a location and energy requirement for each of at least one compressor as part of the gas transmission network based on the geospatial data and simulated network and determine an energy consumption of the gas transmission network based on the energy requirement of each of the at least one compressor.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIG. 1 depicts an example of a gas transmission system.

FIG. 2 depicts a gas transmission energy management system in accordance with one or more embodiments.

FIG. 3 depicts a representation of a gas transmission network in accordance with one or more embodiments.

FIG. 4 depicts an optimization routine in accordance with one or more embodiments.

FIG. 5 depicts a flowchart for training an AI model in accordance with one or more embodiments.

FIG. 6 depicts a gradient boosting machine model for use with, or as part of, the gas transmission energy management system in accordance with one or more embodiments.

FIG. 7 depicts a graph neural network for use with, or as a part of, the gas transmission energy management system in accordance with one or more embodiments.

FIG. 8 depicts a graph in accordance with one or more embodiments.

FIG. 9 depicts a method in accordance with one or more embodiments.

FIG. 10 depicts a system in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before,” “after,” “single,” and other such terminology. Rather, the use of ordinal numbers is to distinguish between the elements. By way of an example, a first element is distinct from a second element, and the first element may encompass more than one element and succeed (or precede) the second element in an ordering of elements.

It is to be understood that the singular forms “a,” “an,” and “the” include plural referents unless the context clearly dictates otherwise. Thus, for example, reference to “predicted performance” can include reference to one or more such performance predictions.

Terms such as “approximately,” “substantially,” etc., mean that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

It is to be understood that one or more of the steps shown in the flowchart may be omitted, repeated, and/or performed in a different order than the order shown. Accordingly, the scope disclosed herein should not be considered limited to the specific arrangement of steps shown in the flowchart.

Although multiple dependent claims are not introduced, it would be apparent to one of ordinary skill that the subject matter of the dependent claims of one or more embodiments may be combined with other dependent claims.

Embodiments disclosed herein relate to a gas transmission energy management system. As will be demonstrated, the gas transmission energy management system provides functionality for evaluating (e.g., estimating energy consumption and carbon intensity), designing, and optimizing gas transmission networks. Energy, in the form of natural gas, can be transported to one or more customers such as a local distributor using gas transmission pipelines. One or more gas transmission pipelines can be connected to form a network.

Globally, the energy landscape is increasingly relying on natural gas as a source of energy to achieve lower carbon emissions compared to traditional fuels. Thus, it is beneficial for a producer and/or supplier of natural gas to estimate operational costs, energy consumption, and carbon intensity associated with transporting natural gas using a gas transmission network. For example, accurate estimations of operational costs, energy consumption, emissions, and carbon intensity of gas transmission networks is important to ensure effective energy management. Further, such estimates are needed to design, construct, and update gas transmission networks in view of goals related to climate change mitigation and energy infrastructure optimization. Further yet, these estimates are useful for policymakers, energy companies, and researchers to enhance sustainability in natural gas transmission networks.

However, estimating these quantities for any given gas transmission network is a difficult task. Despite the increasing use of natural gas globally for energy, there are no platforms that effectively integrate climate conditions, geospatial data including elevation, thermodynamics, and fluid mechanics to determine quantities such as energy consumption and carbon intensity emission.

The gas transmission energy management system described herein integrates climate conditions, geospatial data including elevation, thermodynamics, and fluid mechanics to determine, among other things, energy consumption and carbon intensity emission. In one or more embodiments, the gas transmission energy management system further includes a mechanism for generating training data that is used to train one or more artificial intelligence (AI) models that for use in, or considered part of, the gas transmission energy management system. In one or more embodiments, the gas transmission energy management system includes an optimizer (or optimization routine) that is used for designing a new gas transmission network, determining an update or alteration to one or more equipment items of a gas transmission network, determining an updated setting for one or more controllable parameters related to the operation of a gas transmission network, or combinations thereof. As will be described in the instant disclosure, the gas transmission energy management system includes a physics-based model that is applied to gas transmission networks around the world using publicly available data and default values reported in the literature. Literature references used for supplying the default values, and other information related to gas transmission networks, are provided herein. However, some values may be tuned or altered according to observed data (e.g., validation data) or adjusted according to new literature references or literature references considered to be more accurate. That is, gas transmission energy management system described herein is not limited to using the cited literature references.

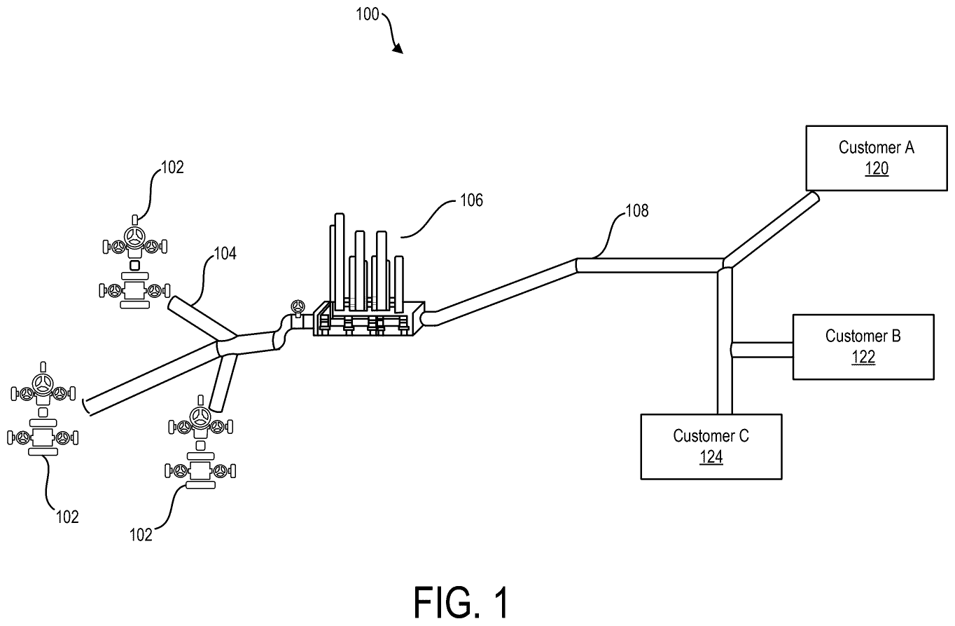

FIG. 1 depicts a simple example of a gas transmission system (100). The gas transmission system includes one more production (or producing) wells (102). In FIG. 1, a wellhead is depicted for each production well (100). A production well (102) is used to extract a production fluid from the subsurface, where the subsurface contains, for example, a reservoir. The production fluid can be multi-phase and be composed of a variety of solid, liquid, and gaseous constituents. For example, the production fluid may contain solid particulates such as sand, mineral precipitates such as pipe scale, and corroded pipe, liquid such as water, and gases like carbon dioxide (CO2) and hydrogen sulfide (H2S). The production fluid may further include desired hydrocarbons, such as oil and gas. A gathering system, usually made up of small-diameter, low-pressure gathering pipelines (104), convey the raw production fluid from the production well(s) (102) to a processing facility (106).

A detailed description of a processing facility (106), and its variants, exceeds the scope of this disclosure. Herein, a processing facility (106) is described as a facility that is configured to receive the raw production fluid from one or more production wells (102) via the gathering system (e.g., gathering pipeline(s) (104)) and output, among other things, a stream of natural gas (hereafter simply referred to as “gas”) having been separated from the other constituents of the raw production fluid and at least partially refined.

The processing facility (106) may include a knock-out drum. The knock-out drum performs bulk separation of gas and liquid. Liquid, separated from the raw production fluid, exits the knock-out drum through a liquid exit. From the knock-out drum, the bulk gas may be processed by a filter separator. A filter separator removes impurities such as mineral precipitates (e.g., pipe scale), water, liquid hydrocarbons, and iron sulfide from the fluid. A filter separator uses filter elements, such as a replaceable sock or a coalescing filter, rather than mechanical components to separate out contaminants. According to the application, a filter separator may be composed of 1 or 2 stages and may operate at high or low pressure. Again, the unwanted portions of the production fluid exit the filter separator through an exit. After the filter separator, the production fluid has been reduced to a gaseous stream. The gaseous stream can undergo additional purifying processes. For example, the processing facility (106) can include an amine contactor. An amine contactor absorbs carbon dioxide (CO₂) and/or hydrogen sulfide (H2S) contaminants from the gaseous stream. In general, an amine contactor, receives the partially processed production fluid, or gaseous stream, and a “lean” amine liquid. Common amines are diethanolamine (DEA), monoethanolamine (MEA), methyldiethanolamine (MDEA), diisopropanolamine (DIPA), and aminoethoxyethanol (Diglycolamine) (DGA). The contact between the gaseous stream and the lean amine liquid drives the absorption of CO2 and/or H2S into the amine liquid from the gaseous stream. As a result, decontaminated gas, also known as “sweetened gas,” may exit the amine contactor. The decontaminated gas can be checked to make sure it meets specifications. The processes of the knock-out drum, filter separator, and amine contactor effectively transform the raw production fluid to a decontaminated gas and complete the objective of the processing facility (106). However, additional processes may be required to maintain the gas processing facility in an operational state. For example, the liquid amine that has absorbed the unwanted CO2 and H2S, which is called “rich” amine, can be sent to an amine stripper for removal of its contaminants and re-conditioning. The use of an amine stripper, for example, using a flash drum and heat exchanger, is not described herein.

It is noted that a processing facility (106) may implement different processes and mechanisms for achieving adequate gas processing than those previously described. Some processes may include compression, stabilization, and dehydration. The processing facility (106) may also encompass the treatment of removed water for disposal through processes such as filtration and deionization. Additionally, elements for heating and cooling may be provided to prevent the formation of hydrates, and mitigate corrosion and aid in dehydration, respectively. With respect to decontaminating and/or refining the raw production fluid, other chemical and physical washes may be used.

Upon exiting the processing facility (106), the separated and at least partially refined natural gas (“gas”) is delivered into a gas transmission network (108) including at least one gas transmission pipeline. The gas transmission pipelines of the gas transmission network (108) are typically wide-diameter and high-pressure relative to the gathering pipelines. A gas transmission pipeline can span large distances, e.g., hundreds of kilometers. As described later in the instant disclosure, the gas transmission network (108) includes one or more compressor stations (or pumping stations) to maintain fluid flow in view of pressure losses from changes in elevation, friction, etc.

The gas transmission network (108) provides the gas to one or more customers. FIG. 1 depicts three customers, namely, Customer A (120), Customer B (122), and Customer C (124). However, a gas transmission network (108) can supply gas to a different number of customers, e.g., one customer, two customers, etc. A customer can be an end user of the supplied gas or a local distributor (e.g., distribution company) or a processing plant or a liquefaction plant. A local distributor can deliver the gas to consumers, for example, through service lines to the locations of the consumers (e.g., individual residences). A liquefaction plant can produce LNG for shipping.

It is emphasized that FIG. 1 provides a simple example of a gas transmission system (100). Other variations of a gas transmission system (100) including additional components such as storage tanks, underground storage, meters, etc., or components not depicted in FIG. 1 such as compressor stations, can be used with embodiments of the instant disclosure. Thus, the depicted example gas transmission system (100) is not to be considered limiting.

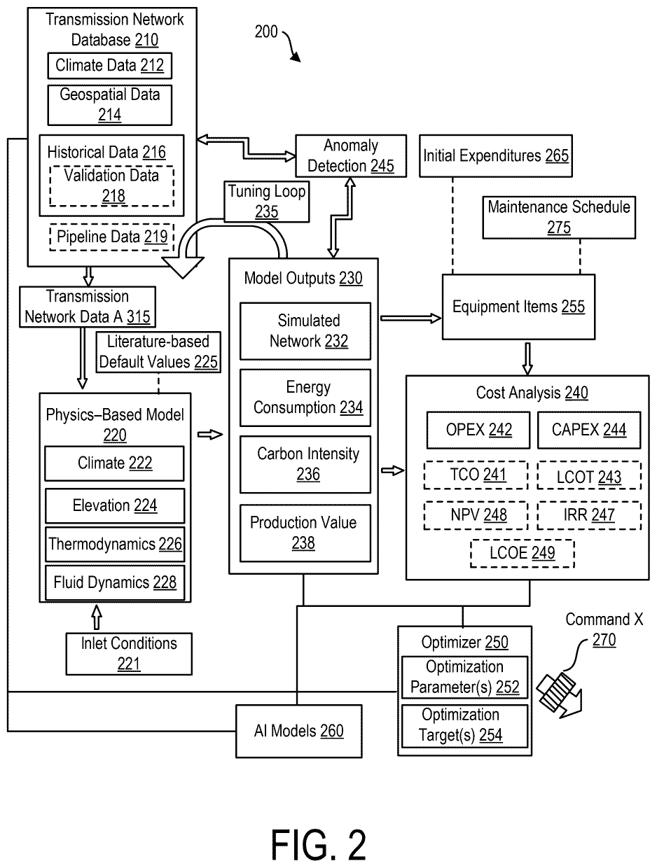

FIG. 2 depicts the gas transmission energy management system (200) in accordance with one or more embodiments. In FIG. 2, the gas transmission energy management system (200) is depicted as being comprised of various components and/or modules, where the components and/or modules may interact with each other. One with ordinary skill in the art will recognize that the partitioning, organization, and interaction of the components and/or modules of the gas transmission energy management system (200) in FIG. 2 is intended to promote clear discussion and should not be considered fixed or limiting.

In one or more embodiments, the gas transmission energy management system (200) includes a transmission network database (210) containing transmission network data for one or more gas transmission networks. Transmission network data for one or more gas transmission networks can take a variety of forms, such as a matrix or one or more tables. In general, transmission network data for a given gas transmission network is obtained through a transmission network analysis. Transmission network data of a gas transmission network includes, at least, climate data (212) and geospatial data (214) including elevation information. For some gas transmission networks, the gas transmission data can further include historical data (216) and/or pipeline data (219). Thus, FIG. 2 depicts the transmission network database (210) as including climate data (212), geospatial data (214), and possibly historical data (216) and pipeline data (219) for one or more gas transmission networks.

Climate data (212) includes, at least, an expected ambient, or environmental, temperature for the location of the gas transmission network. In some implementations, the temperature is an average temperature for the location of the gas transmission network over some spatial and/or temporal period. In some implementations, the climate data (212) includes temperature data that varies spatially and/or temporally. For example, the temperature data can contain an average daily or hourly temperature for a location of the gas transmission network for each day of the year. For gas transmission networks that span large areas and or experience large changes in elevation, different temperature values can be provided for different portions of the gas transmission network, e.g., for individual gas transmission pipelines of the gas transmission network or based on elevation.

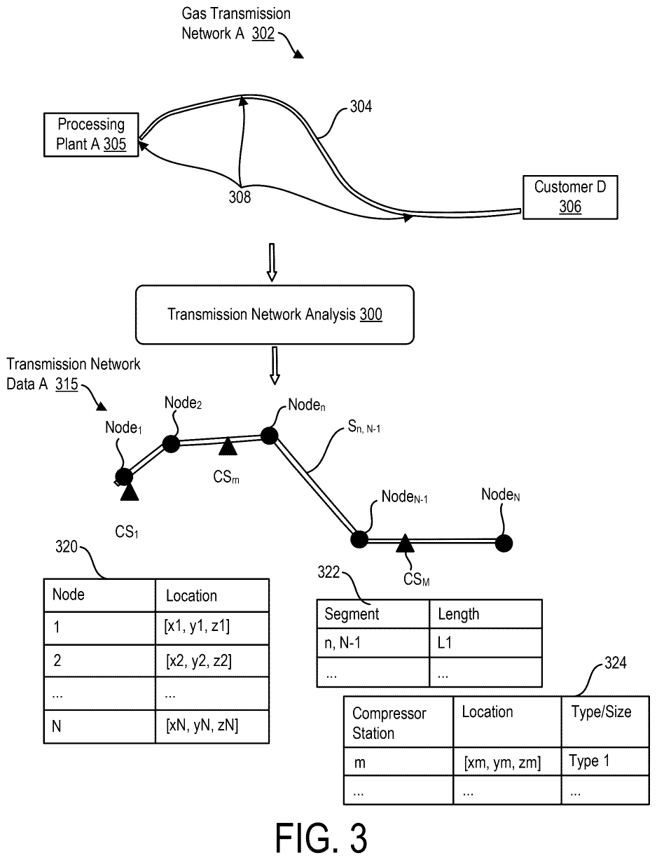

As will be described with respect to FIG. 3, the geospatial data includes a three-dimensional location coordinate for determined nodes of the gas transmission network. The transmission network analysis determines, or discretizes, the gas transmission network into segments. Segments can be formed, for example, by portions of the pipeline that proceed in a relatively straight path. That is, a node may be located at a connection or bend of a gas transmission pipeline in a gas transmission network. In one or more embodiments, the three-dimensional location coordinate for each node includes a longitude, latitude, and elevation (relative to some datum such as sea level).

For some gas transmission networks, historical data (216) may be available and stored as part of the transmission network data of the associated gas transmission network. Historical data (216) includes any measured quantity obtained during operation of the gas transmission network. Examples of measured quantities include, but are not limited to, temperature and pressure measurements acquired from respective sensors disposed along the pipeline or at a wellhead and flow rate measurements from a flow meter such as a multiphase flow meter. In some scenarios, elements of the historical data (216), if available, and can be annotated as validation data (218). Validation data (218) can include the measured values of quantities that are predicted by the physics-based model (220) of the gas transmission energy management system (200), described below. Thus, the validation data (218) can be used to check the output of the physics-based model (220) and further be used to tune or update parameters of the physics-based model (220) in a tuning loop (235), also described below.

For some gas transmission networks, the transmission network data can include pipeline data (219). The pipeline data (219) can include characteristics or properties of the gas transmission network such as the diameter(s) of its gas transmission pipelines and/or locations (and possibly types and/or efficiency values) of compressor stations.

Turning to FIG. 3, FIG. 3 depicts processes of a transmission network analysis in accordance with one or more embodiments. The transmission network analysis is used to obtain, at least, geospatial data (214) for given gas transmission network. FIG. 3 depicts gas transmission network A (302) which is composed of a single gas transmission pipeline (304) that transports gas from processing plant A (305) to customer D (306). For the example of FIG. 3, the locations of various compressor stations (308) are known and depicted.

The transmission network analysis (300) is used to form a digital representation of the gas transmission network (e.g., gas transmission network A (302)). The digital representation includes, at least, the generation of geospatial data (214) for the gas transmission network, however, in some instances, additional data such as pipeline data (219) can be produced by the transmission network analysis (300). The transmission network analysis (300) discretizes the gas transmission pipeline(s) (e.g., gas transmission pipeline (304)) into straight segments and the segments are connected by nodes. The transmission network analysis (300) further determines a three-dimensional location coordinate for each node and a length of each segment where these quantities are included in the geospatial data (214). The transmission network analysis (300) can consult, or has access to, map information (e.g., an overhead or sky view of the gas transmission network relative to an absolute or world coordinate system (e.g., GPS), topological information, etc.) to determine, or assign, the three-dimensional location coordinate for each node. In one or more implementations, the three-dimensional location coordinate for each node consists of a longitude, latitude, and elevation (e.g., relative to sea level). Further, in some implementations that employ longitude and latitude information for the nodes, the length of each segment is computed using, at least in part, the Haversine formula based on the latitude and longitude of the nodes that bound the segment. In some implementations, the length of each segment is computed as the L2 norm of the three-dimensional location coordinates of its bounding nodes.

FIG. 3 depicts a graph representation and tabular data for the gas transmission network A (302) as output, or determined, by the transmission network analysis (300). The graph representation and tabular data are said to be part of the transmission network data for the gas transmission network data A (302), i.e., part of transmission network data A (315). As seen in FIG. 3, the gas transmission pipeline (304) was discretized into four segments using a total of five nodes. In general, the nodes of a gas transmission network can be labelled from 1 to N, where N>2. An index of n can be used to reference a node such that n can take on any value bounded by the range [2, N]. Similarly, the segments can be labelled in a variety of ways, such as by referencing the labels of their bounding nodes. For example, the segment between node n and node N−1 can be labelled or referenced as S(n, N−1). Further, compressor stations can be labelled using an index m where the gas transmission network can include M compressor stations (CSₘ). In some implementations, compressor stations are further labelled according to their associated gas transmission pipeline and/or segment. Transmission network data can be stored in one or more tables (or matrices).

FIG. 3 depicts various tables for storing the transmission network data of gas transmission network A (302) including a node table (320), a segment table (322), and a compressor station table (324). The node table (320) includes, at least, the three-dimensional location coordinate for each node where the coordinate in FIG. 3 is depicted as an array or vector consisting of an x-coordinate (e.g., latitude), a y-coordinate (e.g., longitude), and a z-coordinate (e.g., elevation). The segment table (322) includes, at least, a length of each segment. In accordance with one or more embodiments, the length of each segment is computed based on the three-dimensional location coordinates of its bounding nodes. The segment table (322) can also include, for example, a diameter of the gas transmission pipeline used in the segment and/or other information such as the age of the gas transmission pipeline used in the segment. Age of a segment and/or gas transmission pipeline can be useful, for example, in consideration of corrosion or scale build up in a segment/pipeline. The compressor station table (324) includes all available information related to the compressor stations of the gas transmission network. This information can include, but is not limited to, the location, type and/or size, and efficiency value of the compressor station(s). The graph representation of a gas transmission network can be formed, for example, using the node table (320). In accordance with one or more embodiments, the geospatial data (214) for a gas transmission network includes, at least, the node table (320) for the gas transmission network. The geospatial data (214) can further include the segment table (322). The compressor station table (324), if available, can be included in the pipeline data (219) of the given gas transmission network.

Returning to FIG. 2, and in accordance with one or more embodiments, the gas transmission energy management system (200) includes a physics-based model (220). The physics-based model (220) can receive the transmission network data for one or more gas transmission networks and produce model outputs (230) corresponding to the one or more gas transmission networks. FIG. 2 depicts transmission network data A (315), acquired from the transmission network database (210) (i.e., a database of transmission network data for at least one gas transmission network), being passed to the physics-based model (220). This physics-based model (220), as explained below, determines changes in the pressure and temperature of the gas as it flows though the gas transmission network while considering the climate (222) (i.e., climate data (212)), elevation (from geospatial data (214)), thermodynamic (226) properties of the gas, and fluid dynamics (228) of the gas, based on some inlet conditions (221) (or boundary conditions) (e.g., an inlet temperature and pressure of the gas into the gas transmission network). In some implementations, the inlet conditions (221) are given, or known, as part of the transmission network data for a given gas transmission network (i.e., inlet conditions can be included in the transmission network database (210)). In other implementations, the inlet conditions (221) are not known for a given gas transmission network and are instead estimated from literature-based default values (225).

As depicted in FIG. 2, the physics-based model (220) has access to literature-based default values (225). The literature-based default values (225) include a value for any quantity that may not be known for a gas transmission network. Examples quantities that may have a default value in the literature-based default values (225) include, but are not limited to: a pipeline diameter; an efficiency of a compressor station; a spacing or distance between compressor stations; an inlet temperature; an inlet pressure; a pipeline material; a thermal conductivity of a pipeline (which may further be based on pipeline material and/or temperature); a thermal capacity of the gas (which may also be temperature dependent); and a convection heat transfer coefficient. In some implementations, the default values may depend on other properties or descriptors of the gas transmission network, such as the country in which the gas transmission network resides. In accordance with one or more embodiments, any variable or quantity required by the physics-based model (220), where these quantities will be outlined below in discussion of the equations employed by the physics-based model (220), that is not provided with, or contained in, the transmission network data for a given gas transmission network, is supplemented with a default value from the literature-based default values (225). Table I enumerates literature documents that serve as a reference for one or more values contained in the literature-based default values (225). In discussion of the physics-based model (220), the reference number for a literature document listed in Table I used for a literature-based default value will be indicated, as appropriate.

TABLE I
Literature Documents that form the basis for
the literature-based default values (225)

| Reference | |
|---|---|
| Number | Literature Document |
| [1] | S. Xu, J. Wang, H. Sun, L. Huang, N. Xu, and Y. Liang, “Life cycle |
| | assessment of carbon emission from natural gas pipelines,” Chemical |
| | Engineering Research and Design, vol. 185, pp. 267-280, 2022/09/01/ |
| | 2022, doi: https://doi.org/10.1016/j.cherd.2022.07.018. |
| [2] | G. Molnar, “Economics of gas transportation by pipeline and LNG,” in |
| | The Palgrave handbook of international energy economics: Springer |
| | International Publishing Cham, 2022, pp. 23-57. |
| [3] | N. US. “The Transportation of Natural Gas.” |
| | http://naturalgas.org/naturalgas/transport/ |
| [4] | Y. Ruan et al., “A procedure to design the mainline system in natural gas |
| | networks,” Applied Mathematical Modelling, vol. 33, no. 7, pp. 3040- |
| | 3051, 2009/07/01/ 2009, doi: https://doi.org/10.1016/j.apm.2008.10.008. |
| [5] | G. Ficco, M. Cassano, G. Cortellessa, F. Zuena, and M. Dell'Isola, “On the |
| | Reliability of Temperature Measurements in Natural Gas Pipelines,” |
| | Sensors, vol. 23, no. 6, p. 3121, 2023. |
| [6] | Kaggle. “Mean temperature for countries by year 2014-2022.” |
| | https://www.kaggle.com/datasets/palinatx/mean-temperature-for- |
| | countries-by-year-2014-2022?resource = download (accessed. |
| [7] | ASME. “ASME B31.8: Gas Transmission and Distribution Piping |
| | Systems.” https://law.resource.org/pub/us/cfr/ibr/002/asme.b31.8.2003.pdf |
| | (accessed 15 May, 2024). |
| [8] | M.-w. Fan, C.-c. Ao, and X.-r. Wang, “Comprehensive method of natural |
| | gas pipeline efficiency evaluation based on energy and big data analysis,” |
| | Energy, vol. 188, p. 116069, 2019/12/01/ 2019, doi: |
| | https://doi.org/10.1016/j.energy.2019.116069. |
| [9] | L. J. Muhammad Jabbar. upstream_Alldata_MasterResults_AllCountries |
| | w.US clusterflaring.xlsx. |
| [10] | M. Doble, “Perry's chemical engineers' handbook,” McGraw-Hil, New |
| | York, US, 2007. |
| [11] | M. Vollmer, “Newton's law of cooling revisited,” European Journal of |
| | Physics, vol. 30, no. 5, p. 1063, 2009. |
| [12] | E. Edge, “Overall heat transfer coefficient table charts and equations,” ed, |
| | 2023. |
| [13] | E. Chiavazzo, L. Ventola, F. Calignano, D. Manfredi, and P. Asinari, “A |
| | sensor for direct measurement of small convective heat fluxes: Validation |
| | and application to micro-structured surfaces,” Experimental Thermal and |
| | Fluid Science, vol. 55, pp. 42-53, 2014. |
| [14] | E. Ranjbarnodeh, S. Serajzadeh, A. H. Kokabi, and A. Fischer, “Effect of |
| | welding parameters on residual stresses in dissimilar joint of stainless steel |
| | to carbon steel,” Journal of Materials Science, vol. 46, no. 9, pp. 3225- |
| | 3232, 2011/05/01 2011, doi: 10.1007/s10853-010-5207-8. |
| [15] | V. P. Isachenko, V. A. Osipova, and A. S. Sukomel, Heat transfer. Nirali |
| | Prakashan, 1980. |
| [16] | D. W. Green, “Perry's chemical engineers',” Handbook-seventh Edition- |
| | Sections, pp. 5-12, 2008. |
| [17] | M. Moshfeghian. “Variation of Natural Gas Viscosity with Temperature, |
| | Pressure, and Relative Density.” |
| | https://www.petroskills.com/en/blog/entry/dec2022-totm (accessed |
| | August, 2023). |
| [18] | M. Farzaneh-Gord, A. Arabkoohsar, and R. N. N. Koury, “Novel natural |
| | gas molecular weight calculator equation as a functional of only |
| | temperature, pressure and sound speed,” Journal of Natural Gas Science |
| | and Engineering, vol. 30, pp. 195-204, 2016/03/01/ 2016, doi: |
| | https://doi.org/10.1016/j.jngse.2016.02.018. |
| [19] | A. L. Lee, M. H. Gonzalez, and B. E. Eakin, “The viscosity of natural |
| | gases,” Journal of petroleum technology, vol. 18, no. 08, pp. 997-1000, |
| | 1966. |
| [20] | J. Li and B. Yu, “Chapter One - Gas properties, fundamental equations of |
| | state and phase relationships,” in Sustainable Natural Gas Reservoir and |
| | Production Engineering, vol. 1, D. A. Wood and J. Cai Eds.: Gulf |
| | Professional Publishing, 2022, pp. 1-28. |
| [21] | C. Desgranges and J. Delhommelle, A Mole of Chemistry: An Historical |
| | and Conceptual Approach to Fundamental Ideas in Chemistry. CRC Press, |
| | 2020. |
| [22] | Y. A. Çengel and M. A. Boles, Thermodynamics: An Engineering |
| | Approach. McGraw-Hill Higher Education, 2006. |
| [23] | K. Jeong et al., “A Joule-Thomson Loop to Study High-Pressure Fluid |
| | Expansion,” Energy & Fuels, 2024. |
| [24] | W. Long, “Improving the Oil Production Greenhouse Gas Emissions |
| | Estimator (Opgee): Validation, Modeling, and System Design,” Stanford |
| | University, 2023. |
| [25] | E. Liu. Pathway and distance estimation of LNG transmission lines: |
| | method and dataset. |

For example, the standard thicknesses of gas transmission pipelines based on the pipeline diameter are contained in the literature-based default values (225). The standard thicknesses are obtained from Table 842.214 of reference [7] (ASME B31.8-2003) assuming the gas transmission pipeline(s) is buried at a depth of 2.5 m (approximately 8 ft). This information is provided below in Table II. As will be discussed later in the instant disclosure, the thickness is needed to estimate the heat transfer between the gas and its surrounding environment though the gas transmission pipeline(s).

TABLE II
Grouped standard ASME B31.8-2003, Table 842.214 [7], assuming
that the pipeline is buried at a depth of 8 ft (2.5 m approximately).

| Pipe size (in) | Thickness (in) |
|---|---|
| <6 | 0.3 |
| 6-12 | 0.37 |
| 12-18 | 0.38 |
| >18 | 0.44 |

Keeping with FIG. 2, the physics-based model (220) receives transmission network data (e.g., transmission network data A (315)) for at least one gas transmission network from the transmission network database (210) and determines model outputs (230). The physics-based model (220) is also provided inlet conditions (221) and literature-based default values (225), where the inlet conditions (221) may come from the literature-based default values (225). For a given gas transmission network, the model outputs include a simulated network (232), an energy consumption (234), a carbon intensity (236), and a production value (238). These model outputs (230) are made clear in discussion of the processes and equations employed by the physics-based model (220) below.

An overview of the physics-based model (220) is as follows. The physics-based model (220) applies a simple approach for modelling the complex process of gas transmission though a gas transmission network while considering: (i) climate (222) and elevation (224) conditions; (ii) thermodynamics (226); and (iii) fluid dynamics (228). The physics-based model (220) is then able to determine energy consumption (234), carbon intensity (236), associated costs (see cost analysis (240)), and other quantities. Regarding (i), climate (222) and elevation (224) conditions define the climate-driven energy demands and pressure drops across pipelines based on changes in elevation and ambient temperature, respectively. For (ii), the physics-based model (220) incorporates thermodynamics (226) using an assumption that the gas behaves according to a compression-modified ideal gas law, where the ideal gas law (PV=nRT) is modified by a compressibility factor (Z) of the gas to account for real gas behavior under varying pressure and temperature conditions across the gas transmission network due to geographical conditions, ambient temperature, and pipeline design. Pressure drops in pipelines also arise from elevation changes and equipment like valves and fittings, and these drops are influenced by the viscosity and density of the gas, which vary with temperature and pressure. Temperature changes along the pipeline, influenced by ambient conditions and Joule-Thomson effects, further complicate thermodynamic analysis. The volumetric flow rate, essential for determining mass flow, is altered by these pressure and temperature variations as well. For (iii), incorporation of fluid dynamics (228) into the physics-based model (220) includes calculating the Reynolds number, which distinguishes between laminar and turbulent flow regimes, to determine friction factors for various portions of the gas transmission network. The friction factors affect pressure drops due to friction and the geometry of the gas transmission pipeline(s). All of these factors are used, by the physics-based model (220), to estimate the work required by compressors (i.e., compressor stations) to maintain desired flow rates and pressures. Further, compressor efficiency is used to determine energy consumption (234) and carbon intensity (236), among other things. With the model outputs (230), a cost analysis (240) can be performed to determine, among other things, the capital expenditure (CAPEX) and operating expenses (OPEX) of the gas transmission network. The cost analysis (240) can be informed by the initial costs (e.g., initial expenditures (265) and expected maintenance costs (e.g., maintenance schedule) of equipment times of the gas transmission network.

In accordance with one or more embodiments, the physics-based model (220) implements the following processes. The physics-based model (220) makes use of various simplifying assumptions. These assumptions include: 1) the gas is modelled using a compressibility-modified ideal gas law; 2) adiabatic compression (meaning there is no heat exchange between the compressor and the surroundings); 3) negligible heat transfer between gas and the pipeline; 4) steady-state flow (pipeline conditions do not change with time); 5) isentropic compression (the compression process is reversible and adiabatic); and 6) constant gas composition (the composition of the natural gas remains constant throughout the gas transmission network).

With respect to assumption (3), it is noted that below heat transfer from the gas to the environment is considered. The assumption of negligible heat transfer between the gas and the pipeline is a simplification reflecting that when pipelines are buried, the soil provides substantial thermal insulation. This insulation reduces the direct influence of ambient temperature variations on the gas temperature during its flow, thereby minimizing the immediate heat exchange between the gas and the pipe wall. However, the ambient temperature still plays a role in the overall thermal profile of a gas transmission network, affecting the wall temperature of its pipelines over longer time scales, and can indirectly impact gas temperature and pressure losses. Thus, as described below, while it may be assumed that the heat transfer between the gas and a pipeline is negligible for short-term energy balance calculations (especially at a gas inlet), ambient temperature effects on pipeline walls are accounted for in the broader model (the gas transmission network), ensuring that the impact on pressure losses is appropriately captured.

With the above-described assumptions in place, the physics-based model (220) begins by obtaining inlet conditions (221) for the gas transmission network. The inlet conditions (221) include, for each inlet of the gas transmission network, an inlet temperature, an inlet pressure, and an inlet volumetric flow rate (e.g., in kbbl/d). If not known for the given gas transmission network, the inlet pressure can be acquired from the literature-based default values (225) according to a size and/or pipeline diameter used in the gas transmission network. For example, three suggested values are considered from the literature documents as follows. From reference [1]: Transmission pipelines pressure for one of the largest transmission network in China is 6.8 MPa to 9.85 MPa (Average: 8.3 MPa; Max: 9.85 MPa). From reference [2]: Transmission pipelines are large-diameter pipelines (16-56 inches) operating under high pressure (15-120 bar) and transporting cleaned, dry natural gas through long distances from the processing plant either directly to large end-consumers (such as power plants or industrial sites) or to the city gate where it connects to the distribution system. In gas transmission networks of this nature the average inlet pressure is 6.7 MPa and the maximum inlet pressure is 12 MPa. From [3]: Natural gas that is transported through interstate pipelines travels at high pressure in the pipeline, at pressures anywhere from 1.37 MPa to 10.34 MPa. This reduces the volume of the natural gas being transported (by up to 600 times), as well as propelling natural gas through the pipeline. To summarize this literature document, the average inlet pressure is 5.8 MPa and the maximum inlet pressure is 10.34 MPa. Thus, the average of the maximum values found in the literature is (10.34 MPa+12 MPa+9.85 MPa)/3=10.73 MPa. Further, according to reference [8], a comprehensive method of natural gas pipeline efficiency evaluation based on energy and big data analysis, the average inlet pressure is 6.5 MPa and the average inlet temperature is 19.85 °C. For the volumetric flow rate, the nearest production site is considered in terms of kbbl/d from the dataset of the ETT group of reference [9].

With the given inlet conditions (221), the physics-based model (220) can determine temperature changes along the length of a given gas transmission pipeline due to heat transfer to the environment. In one or more implementations, the outside surface of a gas transmission pipeline is assumed to be at the ambient or environmental temperature. Thus, heat transfer considers the convective transfer of heat from the gas to the inner surface of the pipeline and then the conductive transfer through the pipeline (or from its inner diameter or inner surface to its outer diameter or outer surface). The heat transfer from the fluid to the inner surface of the pipeline is given according to Newton's law of cooling (discussed in reference [11]) according to:

Q_{conv}=h*A(Tᵢ−T_{f}), EQ 1

where, Q is the rate of heat transfer (in Watts), h is the convective heat transfer coefficient (in W/m²·K), A is the surface area of the pipe (in m²), T_{f} is the temperature of the gas, and Tᵢ is the temperature of the inner surface of the pipeline (in Kelvin).

According to reference [12], h, the convective heat transfer coefficient varies between 150 and 500 W/m²·K. In one or more implementations, a value of 325 W/m². K is assumed, and contained in the literature-based default values (225), based on reference [13]. The pipe surface area is calculated as

A=2*π*r*L, EQ 2

where r is the radius of the inner surface of the pipeline (in meters) and L is the length of the pipeline (in meters), or the length of the portion under consideration (i.e., a discretized portion.

Conductive heat transfer through the pipeline (discussed in reference [15]) can be given according to

$${Q}_{c o n d} = \frac{k * A * ( {T}_{i} - {T}_{o} )}{t} , \qquad EQ 3$$

where k is thermal conductivity of the pipeline, t is the thickness of the pipeline (i.e., outer radius minus the inner radius), and Tₒ is the temperature of the outer surface of the pipeline, or the ambient temperature. According to reference [5], the average fluid temperature in the pipe changes along with the ambient temperature. Therefore, in one or more implementations, the annual average ambient temperature is considered, from reference [6], for each country where there is a gas transmission network.

The thermal conductivity is assumed k=36 (W/m*K) based on reference [14]. In some embodiments, EQ 3 is adapted, e.g., using a cylindrical coordinate system, to account for the change in surface area between the inner and outer surfaces of the pipeline.

The heat transfer from the fluid to the inner surface of the pipeline (EQ 2) and from the inner surface of the pipeline to the outer surface of the pipeline (EQ3) is balanced (i.e., assuming no heat storage; steady state) by equating Qconv and Qcond. This results in EQ. 4 such that the temperature of a gas in a segment of a pipeline can be determined in view of the ambient temperature in which that segment resides:

$${T}_{f} = {T}_{i} + ( {T}_{o} - {T}_{i} ) * {( \frac{h * t}{k} )}^{- 1} . \qquad EQ 4$$

Next, the physics-based model (220) applies the Darcy-Weisbach equation to calculate the pressure drop along the pipeline segments due to friction, ΔP_{f} (see reference [16]). This depends on the diameter of the pipeline, the properties of the gas, and the flow rate. Equations 5 and 6, below, are used to estimate pressure drop due to friction.

$$Δ {P}_{f} = \frac{f * L * ρ * {v}^{2}}{2 {D}_{i}} \qquad EQ 5$$

$$f = \{ \begin{matrix}Turbulen flow , & f = 0.00958 * {D}_{i}^{- 0.2} \\ Laminar flow , & f = \frac{64}{Re}\end{matrix} \qquad EQ 6$$

In EQs 5 and 6, f is the friction factor over the segment, L in the length of the segment, ρ is the density and v is the velocity of the gas over the segment, Dᵢ is the inner pipeline diameter over the segment, and Re is the Reynolds number over the segment. The Reynolds number is calculated according to

$$R e = \frac{ρ * v * {D}_{i}}{μ} , \qquad EQ 7$$

where μ is the dynamic viscosity of the gas, kg/(m*s). Inspection of EQs 5, 6, and 7 reveals and implicit structure, wherein the velocity of the gas depends on the pressure drop and the pressure drop depends on the friction factor that is a function of Reynolds number that is function of velocity. In one or more implementations, EQs 5, 6, and 7 are solved using an iterative routine as described in reference [17].

It is noted that the molar mass of natural gas, M can be assumed between 16-22 Kg/kmol based on reference [18]. This can be accurately estimated if the user knows the gas composition. Reference provides EQs 8, 9, 10, and 11 for correlation of viscosity for fluids, which is used to estimate the dynamic viscosity of fluids, particularly for natural gas. In these equations, L₁, L₂, and L₃ are empirical constants, while p is the density of the fluid, and M is a parameter related to the fluid's molecular composition or specific volume. The correlations of reference [19] provide an approximation of viscosity based on the relationship between fluid density, molecular size, and temperature. The physics-based model (220) uses these equations for fluid dynamics (228).

$$μ = {L}_{1} * exp [ {{L}_{2} ( \frac{ρ}{A} )}^{{L}_{3}} ] \qquad EQ 8$$

$${L}_{1} = 1 {0}^{- 4} * \frac{( 7.77 + 0.0 \; 063 * M ) * {T}_{f}^{1.5}}{122.4 + 12.9 * M + {T}_{f}} \qquad EQ 9$$

$${L}_{2} = 2.57 + \frac{1914.5}{{T}_{f}} + 0.0 \; 095 * M \qquad EQ 10$$

L₃=1.11+0.04*L₂ EQ 11

In EQs 8, 9, 10, and 11, A is the cross-section area of the segment, L₁, L₂ and L₃ are correlation factors, and M is the molecular weight of the gas, described above. Further, the flow regime based on the Reynold's number is given as

$$flow regime = \{ \begin{matrix}laminar & if Re < 2000 \\ transitional & if 2000 \leq Re \leq 4000 \\ turbulent & if Re > 4000\end{matrix} .$$

In accordance with EQ 6, the appropriate friction factor is based on the flow regime. For laminar flow, use the Hagen-Poiseuille friction factor: f=64/Re (in EQ 6). For turbulent flow, use empirical correlations such as the simplified Colebrook-White equation for natural gas to calculate the friction factor (see reference [1]): f=0.009588×Dᵢ−^{0.2} (in EQ 6).

The density of the gas is calculated at each point along the pipeline using the compressibility-modified ideal gas law, from reference [10], which relates pressure, temperature, and density as follows.

$$ρ = \frac{{P}_{1} * M}{Z * R * {T}_{f}} \qquad EQ 12$$

In EQ 12, P₁ is the pressure in the pipeline (MPa), T_{f} is the temperature in the gas (K), R is the specific gas constant for natural gas, 8.314 m3*Pa/(K·mol), M is the molar mass of the gas, 0.01604 [kg/mol] (assumed for Methane, though for natural gas it can be assumed 20.3 Kg/kmol), and Z is the compressibility factor

An empirical correlation for the compressibility factor of natural gas is given as

$$Z = \frac{100}{100 + 1.734 * {P}_{1}^{1.15}} . \qquad EQ 13$$

The compressibility factor is used to adjust the ideal gas law for real gas behavior, accounting for deviations due to high pressures and non-ideal conditions. In this equation, the factor 1.7434 and the exponent 1.15 are empirical constants determined through experimental data, and they vary based on the specific type of gas and its conditions, particularly at moderate to high pressures.

Next, the physics-based model (220) uses the hydrostatic pressure equation to calculate the pressure drop due to changes in elevation in each segment, ΔPₕ. The hydrostatic pressure equation is given as

ΔPₕ=ρ*g*Δh, EQ 14

where ρ is the density of the gas (in kg/m³ or lb/ft³), g is the acceleration due to gravity (in meters per second squared, m/s²), and Δh is the change in height or elevation (in meters).

Next, the physics-based model (220) determines the distance between compressor stations. According to practical engineering experience, it is most reasonable that the distance between the two compressor stations is from 120 to 160 km according to reference [4]. Thus, in one or more implementations, the physics-based model (220) uses a distance of 140 km between two compressor stations as a default value if the locations of the compressor stations are not known. The pressure drops due to friction and elevation are added up over the distance between compressor stations according to

P_{drop}=ΔP_{f}+ΔPₕ, EQ 15

where ΔP_{f} is the pressure loss due to friction and ΔPₕ is the pressure loss due to elevation over a given segment.

Next, the physics-based model (220) subtracts the pressure drop from the initial pressure to determine the pressure required to be provided by the compressor at the end of each segment. The pressure at the end of each segment is assumed from the literature at 10.73 MPa. Similarly, the temperature at the end of each segment is calculated using the compression-modified ideal gas law (EQ 12), considering the change in pressure. The absolute pressure is estimated using equations 16 and 17, shown below. In EQs. 16 and 17, P₂ is estimated considering the pressure drops and the required pressure P₁ inside the pipeline. P_{drop} is the pressure drop over the segment, T₁ and T₂ are the initial and final temperatures, respectively, P₁ and P₂ are the initial and final pressures, respectively. Results until here align with Guy-Lussac's law (see reference [21]).

$${T}_{2} = \frac{{P}_{2} * {T}_{1}}{Z * {P}_{1}} \qquad EQ 16$$

P₂=P₁−P_{drop}| EQ 17

Next, the physics-based model (220) calculates the final volumetric flow rate at the end of each segment. EQ 20, shown below, is used to calculate the final volumetric flow rate at the end of each segment, considering the change in pressure and temperature. The ideal gas law equation can be rearranged to solve for the final volumetric flow rate. By incorporating the final temperature (T2) (EQ 16) into this equation, the final volumetric flow rate at the end of each segment is determined, considering both pressure and temperature changes under real conditions, considering compressibility factor as well. P2 is estimated considering the pressure drops and the required pressure inside the pipeline for each segment.

$${V}_{2} = \frac{{V}_{1} * {P}_{1} * {T}_{1}}{Z * {P}_{2} * {T}_{2}} \qquad EQ 18$$

In EQ 18, V₁ is the initial volumetric flow rate at the start of the segment, P₂ is the pressure at the end of the segment, and T₁ and T₂ are the start and end temperatures of the segment, respectively

Next, the physics-based model (220) calculates the work done by compressors (or compressor stations). The isentropic compression process is applied to calculate the work done by compressors to increase the pressure of the gas to the required level at each compressor station according to

$${W}_{c} = {\int }_{{V}_{1}}^{{V}_{2}} Z * P * d V = Z * {P}_{1} * ( {V}_{2} - {V}_{1} ) , \qquad EQ 18$$

where W_{c} is the total volumetric work by the compressor, Z is the compressibility factor of the gas over the segment, P₁ is the pressure at the segment start, and V₂ and V₁ are the volumes at the segment end and start, respectively.

If the pressure at the initial point is bigger than 11 MPa, then the energy required for a Pressure Reduction Stations (PRS), using JT valves, is estimated. This estimation makes use of the Joule-Thomson (J-T) effect and the enthalpy change (ΔH) across the JT valve as shown in EQ 19, below. For further calibration, according to the Joule Thomson Effect, a 0.689 MPa pressure drop results in a temperature drop of 3.33 to 4.44 degrees Celsius.

$$Δ H = {\int }_{P 1}^{P 2} V d P = Z * V * ( P 2 - P 1 ) \qquad EQ 19$$

In EQ. 19, ΔH is the enthalpy change across the JT valve and V is the specific volume of the gas.

Next, the physics-based model (220) calculates energy consumption (234) for the gas transmission network. This is done by summing up the work done by all compressors along the pipeline to determine the total energy consumption. The energy required is calculated assuming an efficiency of the compressor, as in EQ 20, below. As in reference [24], efficiency=75% is assumed for reciprocating compressors. The total work required is estimated by multiplying W_{c} times the number of compressors needed. The number of compressors is equal to total length divided by 140 km. The required work of the compressor can be further converted in MW and HP for commercial purposes.

$${E}_{c} = {W}_{c} * {η}_{c}^{- 1} \qquad EQ 20$$

In EQ 20, W_{c} is the work of the compressor, η_{c} is the efficiency of the compressor, E_{c} is the energy required to run the compressor.

Next, the physics-based model (220) uses the emission factor of each national grid to determine the CO₂ emissions produced in compressor stations according to

CO₂ₑ=E_{c}*Grid_{ef}, EQ 21

where E_{c} is the energy consumption by compressors and Grid_{ef} is the emission factor of the grid for each country.

Finally, the physics-based model (220) estimates the emissions and LNG production (e.g., production value (238)) and then uses these quantities to determine carbon intensity (236) in each gas transmission network, according to

$$CI = \frac{{CO}_{2 e}}{L N {G}_{p}} ; [ \frac{{tCO}_{2 e}}{t L N G} ; \frac{k {ℊCO}_{2 e}}{M {J}_{L N G}} ] , \qquad EQ 22$$

where CO₂ₑ are the equivalent CO2 emissions in the gas transmission network, LNGₚ is the annual production of LNG from the gas transmission network, and CI is the carbon intensity (236).

In review, the processes of FIG. 2 as discussed to this point in the instant disclosure produce the information of Table III, below, for a given gas transmission network.

TABLE III
Outputs, or determined quantities, of the gas transmission
energy management system applied to a gas transmission
network, in accordance with one or more embodiments.

Pipeline geometry
Total pipeline length (km)
Distances between consecutive points (m, km)
Pipeline route as geospatial line geometry
Elevation data for all pipeline points (m above or below sea level)
Relative elevation changes between pipeline points (m)
Pipeline dimensions
Average pipeline diameter (inches, meters)
Pipeline wall thickness (inches)
Internal pipeline diameter (inches, meters)
Gas flow properties
Flow rate (m³/s, kbbl/day)
Gas velocity (m/s)
Gas density (kg/m³)
Thermodynamic properties
Gas compressibility factor (Z)
Gas viscosity (dynamic viscosity in centipoise, micropascal-seconds)
Reynolds number (dimensionless, determines laminar or turbulent flow)
Pressure drops
Frictional pressure drops (MPa)
Elevation-induced pressure drops (MPa)
Total pressure drops between compressor stations (MPa)
Pressure at each pipeline point (MPa)
Energy consumption
Work required for compression (MJ/day, GJ/year)
Total energy consumption for pipeline operations (GJ/year, MJ/year)
Compressor efficiency and the number of compressors required
Production metrics
LNG production volume (t/year, kg/year)
Natural gas production energy content (MJ/year, PJ/year)
Electricity usage
Total electricity consumption (PJ/year, GWh/year)
Grid electricity CO₂ emission factor (kgCO₂/MJ)
Carbon emissions
Total CO₂ emissions (kg/year, t/year, kt/year).
Energy consumption converted to CO₂ emissions based on emission factors.
Carbon intensity (CI)
CI in gCO₂/MJ of LNG
CI in tCO₂/t LNG
CI in kgCO₂/kg LNG
Compressing stations
Number of compressing stations
Validation
Smooth handling of outliers in gas velocity and Reynolds number.
Summaries of pipeline metrics grouped by route or country.
Summary
Key pipeline metrics such as pressure, energy, emissions, number of compressors
required, and carbon intensity for all routes, in all countries that are currently doing LNG
business.

As described above, the physics-based model (220) produces various intermediate outputs, such as calculated temperature and pressure values of the gas throughout the gas transmission network according to a prescribed discretization. In one or more implementations, a data point including at least one variable such as temperature is determined by the physics-based model (220) at each node of the gas transmission network. Each data point can include other key variables such as pressure, flow rate, density. The collection of data points is said to form a simulated network (232) of the gas transmission network considered using the physics-based model.

In one or more implementations, transmission network data was collected for every gas transmission network in the world by performing a transmission network analysis (300) to obtain geospatial data (214) for each given gas transmission network. Additionally, where available, public data was obtained for gas transmission networks (e.g., historical data (216)). The transmission network data for each gas transmission network in the world was stored in the transmission network database (210). Then, the physics-based model (220) was used to process the transmission network data of each gas transmission network, using literature-based default values (225) as needed. The physics-based model (220), when applied to every gas transmission network of the world, produced 1.9 million data points for 109 variables in pipelines between fields and processing plants, and 0.7 million data points for 116 variables in pipelines between processing plants and liquefaction plants. Additionally, the network between fields and processing plants has 57275 pipelines, while processing plants and liquefaction plants has 21398 pipelines, globally. Thus, a total of 2.76 million data points were estimated using the physics-based model (220). These data points, i.e., the simulated networks (232) and associated energy consumption (234), carbon intensity (236), and production value (238) are used by the gas transmission energy management system (200) to train a set of artificial (AI) models (260). The process of training an AI model and descriptions of two specific AI models (260) included in the gas transmission energy management system (200) are discussed later in the instant disclosure. It is noted that the above-listed number of data points is based having a data point at each node of each gas transmission network for every gas transmission network of the world. While it is theoretically possible to generate an arbitrary number of data points by increasing spatial resolution (e.g., every meter or centimeter instead of every node), the chosen segment-based resolution reflects a pragmatic balance, capturing all essential variations in pipeline behavior without overwhelming the physics-based model (220). This structured approach ensures that each data point is both meaningful and actionable for training the set of AI models (260), ultimately improving the accuracy and predictive power of the gas transmission energy management system (200).

In one or more embodiments, the gas transmission energy management system (200) includes or performs a tuning loop (235) using the model outputs (230) of the physics-based model (220). The tuning loop (235) compares the model outputs (230), or a portion thereof, to the validation data (218), if available. Validation data (218) can include the measured values of quantities (i.e., the real values) for the model outputs (230) (i.e., the predicted values). The comparison can be used to guide updates to tunable parameters of the physics-based model, such as the heat transfer coefficients, inlet conditions, etc. The model outputs (230) can also be compared to the historical data (216) using an anomaly detection (245) algorithm included in the gas transmission energy management system (200). The anomaly detection (245) algorithm identifies large differences or outliers between the model outputs (230) and the historical data (216). In instances where a large difference (e.g., exceeding a predefined and/or normalized threshold such as deviating by more than two standard deviations) between a historical data value and a model output value is detected, the gas transmission energy management system (200) can: 1) disregard the historical data value for use in the tuning loop (235) if it is annotate as validation data (218); and, 2) flag or indicate to a user that the historical data value may be in error or the symptom of another issue. For example, a historical data value may be the actual energy usage of a given compressor station. In instances where the energy usage of the given compressor station is larger (e.g., greater than two standard deviations) than expected (or as output or predicted by the physics-based model (220)), this can indicate that the compressor station is underperforming or otherwise faulty. Thus, the anomaly detection (245) algorithm can be used to identify underperforming or faulty equipment items.

In review, the gas transmission energy management system (200) includes a robust validation process (tuning loop (235) and validation data (218)) in each step of the calculations (physics-based model (220)) to ensure the reliability of its estimates (model outputs (230)). The system uses detailed input data, such as pipeline networks, local temperature, compressor station frequency, and pipeline diameter, to generate millions of data points, and these calculated outputs (e.g., carbon intensity and operational costs) are cross validated against available real-world measurements, industry benchmarks and scientific literature. The cross validation can also include an anomaly detection (245) process for identifying errors in values and/or associated issues with equipment items.

Keeping with FIG. 2, based on the model outputs (230), the equipment items (255) of a gas transmission network are known. In one or more embodiments, the gas transmission energy management system (200) includes a list, or estimate, of initial expenditures (265) and maintenance schedule (275) (and associated cost of maintenance), for every equipment item. Thus, the cost to construct and maintain a gas transmission network can be determined in view of its required equipment items (255) and used, or included, in a cost analysis (240) for the gas transmission network.

The initial expenditures (265) can include material costs, for example, for gas transmission pipelines based on length, diameter, and material type (e.g., carbon steel, stainless steel), and wall thickness required to withstand the operating pressures. Initial expenditures (265) can also include construction costs related to excavation, welding, installation, and testing for a gas transmission network. The construction costs can consider factors like terrain difficulty, accessibility, and pipeline length. Additional costs that can be considered include land acquisition and permitting, auxiliary facilities (e.g., valve stations, control systems, monitoring equipment, and corrosion protection), compressor station costs (can depend on horsepower or power rating or type of compressor (e.g., electric-driven vs. gas-turbine compressors), cooling systems, and control and safety systems (e.g., SCADA, fire protection, etc.).

In accordance with one or more embodiments, the gas transmission energy management system (200) determines a cost analysis (240) for a given gas transmission network. The cost analysis (240) is based on the model outputs (230) and the equipment items (255) of the gas transmission network (and in view of the associated costs of the equipment items). The cost analysis (240) determines, at least, operating expenses (OPEX) (242) and capital expenditures (CAPEX) (244) for the gas transmission network. In some implementations, the cost analysis (240) includes other cost or economic values for the gas transmission network such as total cost of ownership (TCO) (241), levelized cost of transmission (LCOT) (243), net present value (248), internal rate of return (247), and levelized cost of energy (LCOE) (249).

OPEX (242) considers the power requirements of compressors (depending on the fuel type (e.g., natural gas, electricity) and the unit energy price (e.g., if the compressors use natural gas, the cost is estimated based on the volume of gas consumed for compression), maintenance costs (e.g., costs for scheduled inspections, lubrication, and parts replacement of the pipeline and compressor stations), repair costs (costs for unexpected repairs, considering historical failure rates, especially for compressors and valves), staffing and operations costs (including the wages of operational staff such as engineers, technicians, and maintenance personnel), monitoring and control costs (e.g., cost of control room operations, remote monitoring, and any software subscriptions), emissions compliance costs (e.g., emissions control systems), and carbon credits or penalties (costs related to carbon credits or penalties if the emissions exceed the regulated limits).

TCO (241) includes the total cost of a gas transmission network over time (e.g., a given period such as 20 or 30 years). TCO (241) includes both CAPEX (244) and OPEX (242) estimates, adjusted for inflation and potential cost fluctuations.

LCOT (243) and LCOE (249) are similar in that the each standardize or normalize a cost to transport or produce a unit of gas, respectively. LCOT (243) can also be provided in cost per unit of transported gas per kilometer.

In accordance with one or more embodiments, the gas transmission energy management system (200) includes an optimizer (250). The optimizer (250) is used to determine values for one or more optimization parameters (252) to optimize (e.g., maximize or minimize) one or more optimization targets (254). The optimization parameters (252) and the optimization targets (254) may be defined based on a given usage situation. In a first usage situation, the optimizer (250) is used for the design of a new gas transmission network (e.g., route optimization). Thus, the optimization parameters (252) can be related to the placement of gas transmission pipelines. The optimization target can include, for example OPEX (242) carbon intensity (236), where these quantities are desired to be minimized. In this usage situation, the gas transmission energy management system (200) can simulate multiple pipeline routes by integrating geospatial, terrain, and climate data (i.e., applying the physics-based model to a proposed gas transmission network). Then, the optimizer (250) can evaluate trade-offs between different proposed gas transmission networks. For example, by comparing a gas transmission pipeline with longer routes (with higher friction losses) and shorter, steeper paths (with higher elevation-induced pressure drops), identifying the most cost-efficient design for new pipeline construction to reduce carbon intensity and overall costs. In a second usage situation, the optimizer (250) is used to adjust operational parameters (e.g., choke valve settings) of existing gas transmission networks. In this usage situation, the physics-based model (220) provides real-time estimates of energy consumption, pressure drops, and emissions. Then, the optimizer (250) can use these estimates as optimization targets (253) to adjust operational parameters as optimization parameters (252) such as compressor station settings, adjust flow rates, and operational schedules. In a third usage situation, the optimizer (250) is used to determine a retrofitting priority; or an identification and hierarchy of equipment items that should be replaced to optimize an existing gas transmission network. In this usage situation, the current performance (i.e., historical data (216) is compared with simulation outputs (model outputs (230) to determine where retrofitting, such as upgrading compressors or improving insulation, could yield significant cost savings and emissions reductions. Thus, the optimizer can consider the various costs of equipment items identified as candidates for upgrade/replacement and determine the impact of the upgrade/replacement.

Any of the above-described usages (or usage situations) of the optimizer (250) can be combined. In review, the gas transmission energy management system (200) can be used, for example, with its optimizer (250) for scenario and sensitivity analyses. In a scenario analysis, various what-if scenarios are evaluated (e.g., operational parameters and/or retrofitting) to determine their effect on costs. For example, analyze the cost impact of changing compressor power, pipeline diameter, or switching to electric compressors. In a sensitivity analysis, the sensitivity of cost estimates to various factors like energy price fluctuations, equipment costs, and maintenance frequency is determined. This helps identify which parameters most significantly influence the overall cost.

In accordance with one or more embodiments, the gas transmission energy management system (200) can issue commands (e.g., Command X (270)) to alter or adjust the operation of one or more gas transmission networks. For example, the optimizer (250) can be used to determine an updated setting for an operational parameter of a gas transmission network (e.g., choke valve setting) and the issued command (e.g., Command X (270)) to change the operational parameter to the updated setting. In this way, the gas transmission energy management system (200) can control one or more gas transmission networks.

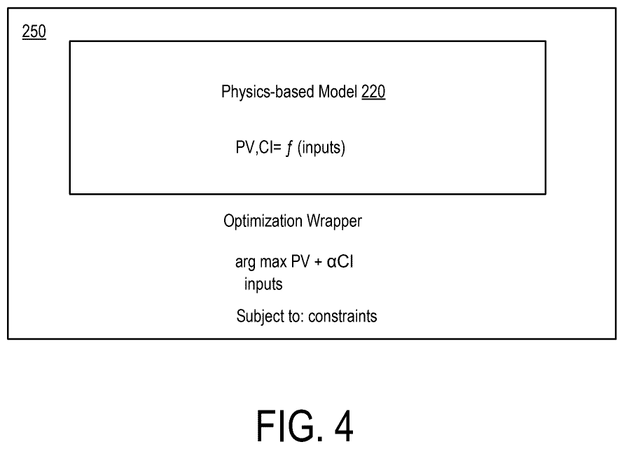

FIG. 4 depicts an embodiment of the optimizer (250) of the gas transmission energy management system (200). In this embodiment, the optimizer (250) is wrapped (or is an optimization wrapper) about the physics-based model (220). The physics-based model (220) may be described as a function relating some given inputs (e.g., pipeline route) and outputs (e.g., carbon intensity). That is, for simplicity, the physics-based model (220) may be mathematically represented as outputs=f (inputs), such that given an input the physics-based model (2220) may produce an output. In one or more embodiments, the physics-based model, upon processing an input, produces two or more outputs (e.g., carbon intensity and production value. In FIG. 4, as an example, two outputs are shown as carbon intensity (CI) and production value (PV). The optimizer (250) may combine the outputs to a single value using a given function or equation. In FIG. 4, as an example, the parameter a is used to weight the carbon intensity (CI) relative to the production value (PV). Then, with the physics-based model (220), the optimization wrapper is used to invert the model to determine the inputs that optimize the outputs, as combined and weighted. Mathematically, the optimization takes the form

$${argmax}_{SI} g ( outputs )$$

subject to: constraints
   where g( ) is function that combines the outputs an SI is a set of controllable inputs, or the portion of the inputs provided to the physics-based model (220) over which the optimization should occur. The optimizer (250) may also consider various constraints, such as device limits (e.g., minimum and/or maximum choke valve settings, maximum allowable pressure for safety, etc.). The set of controllable inputs are the optimization parameters (252) and the outputs are the optimization targets (254). Thus, in FIG. 4, the inputs, outputs, and function g, if needed, can be defined according to a given usage situation or optimization task.

Returning to FIG. 2, the gas transmission energy management system (200) also includes a set of AI models (260). Artificial intelligence (AI), broadly defined, is the extraction of patterns and insights from data. The phrases “artificial intelligence,” “machine learning,” “deep learning,” and “pattern recognition” are often convoluted, interchanged, and used synonymously throughout the literature. This ambiguity arises because the field of “extracting patterns and insights from data” was developed simultaneously and disjointedly among a number of classical arts like mathematics, statistics, and computer science. For consistency, the term artificial intelligence, or AI model or AI-based, will be adopted herein, however, one skilled in the art will recognize that the concepts and methods detailed hereafter are not limited by this choice of nomenclature.

AI model types may include, but are not limited to, neural networks, logistic regression, random forests, generalized linear models, convolutional neural networks, graph neural networks, gradient boosting machines, transformers or other sequence-to-sequence models, k-means clustering, support vector machines, reinforcement models, and time-series models including recurrent neural networks. AI model types are usually associated with additional “hyperparameters” that further describe the model. For example, hyperparameters providing further detail about a neural network may include, but are not limited to, the number of layers in the neural network, choice of activation functions, inclusion of batch normalization layers, and regularization strength. Commonly, in the literature, the selection of hyperparameters surrounding a model is referred to as selecting the model “architecture.” Greater detail regarding the use of one or more AI models, in accordance with one or more embodiments, will be provided below in the present disclosure.

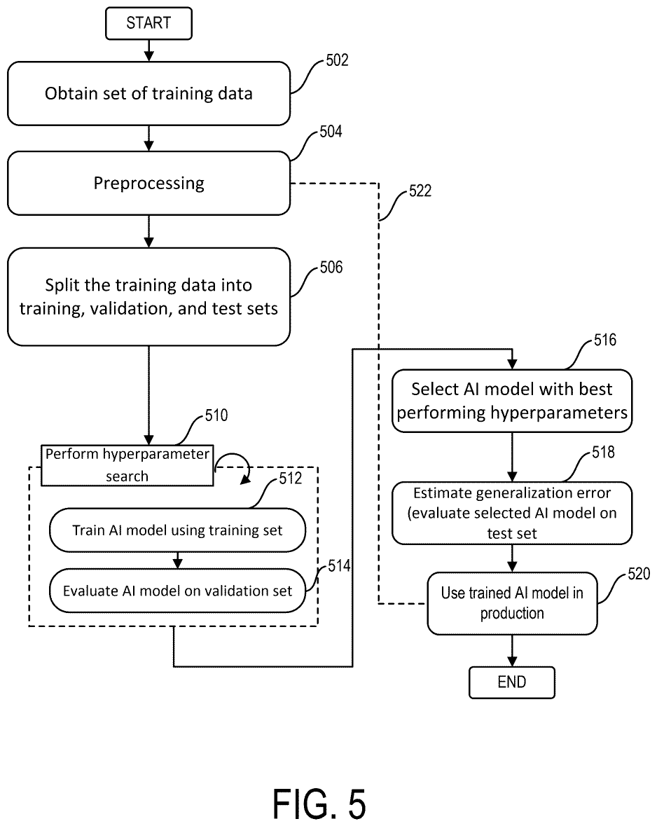

In accordance with one or more embodiments, the transmission network database (210) including gas transmission data for at least one gas transmission network and the associated model outputs (230) are used as the source of training data for one or more AI models (260). In accordance with one or more embodiments, the general process for developing and using an AI model for use in the gas transmission energy management system (200) is depicted in the flowchart of FIG. 5. As shown in Block 502, the process starts by obtaining a set of training data. The selected training data depends on the desired task of the AI model being trained. Below, specific examples of a first AI model and a second AI model included in the set of AI models (260) of the gas transmission energy management system (200) are described. In these examples, the AI model inputs and outputs are described. In in the present discussion, training data consisting of input and output pairs is selected from the transmission network database (210), model outputs (230), and cost analysis (240) from various gas transmission networks having been processed by the physics-based model (220).

In one or more embodiments, the set of training data may be preprocessed as shown in Block 504. Preprocessing, at a minimum, comprises altering the data so that it is suitable for use with machine-learned models. For example, numericalizing categorical data or removing data entries with missing values. Other typical preprocessing methods are normalization and imputation. Normalization is the process of transforming, or scaling, values of the set of training data with an intention to aid the machine-learned model. Imputation is the process of replacing missing values, corrupted values, or outlier values in a set of data with a substitute value so that the data may be used in a machine-learned model. One imputation strategy may be to replace values with the nearest acceptable value in the data set. In one or more embodiments, preprocessing requires the determination of one or more preprocessing parameters (e.g., the mean and standard deviation of a drilling fluid property over the set of training data). In general, information surrounding the preprocessing steps is saved as preprocessing parameters for potential later use. This allows future data instances to be preprocessed identically to those in the set of training data.

One with ordinary skill in the art with recognize that a myriad of preprocessing methods beyond numericalization, removal of modeling data entries with missing values, normalization, and imputation exist. Thus, the enumeration of a select few preprocessing methods herein do not impose a limitation on the preprocessing steps encompassed by this disclosure.

Keeping with FIG. 5, in Block 506, the set of training data is split into training, validation, and test sets. Thus, the nomenclature of the instant disclosure allows for a “set of training data” to include a “training set,” a “validation set,” and a “test set.” In some embodiments, the validation and test set may be the same such that the set of training data is effectively only split into two distinct sets. In one or more embodiments, Block 506 may be implemented before Block 504. In these instances, generally any preprocessing parameters are determined using only the training set. Subsequently, the preprocessing steps are applied to the training set, validation set, and test set using the using the preprocessing parameters determined from the training set. A common splitting method is to randomly select a portion X of the data instances for the training set, a portion Y for the validation set, and assign the remaining portion of samples to the test set. For example, 80% of the data instances may be assigned to the training set, 10% to the validation set, and the remaining 10% to the testing set. However, one with ordinary skill in the art will recognize that other splitting methods and/or set proportions may be used without exceeding the scope of this disclosure.

Once the set of training data is split, the training set, validation set, and test set are used to train, tune, and evaluate and AI model for use in, or with, the gas transmission energy management system (200). Block 510 represents an iterator to cycle over hyperparameters associated with the AI mode being trained and perform the enclosed operations. In other words, in Block 510 associated hyperparameters are selected. The hyperparameters search may be performed using any method known in the art. As non-limiting examples, the hyperparameters search of Block 510 may be performed according to a grid search, a random search, or a Bayesian-based search.

For each set of applied hyperparameters, the AI model is trained using the training set, as shown in Block 512. Once an AI model is trained, its performance is evaluated on the validation set, as depicted in Block 514. In the case where there is no validation set, such as when the set of training data is only split into training and testing sets, the testing set may be used for the validation set. In some embodiments, one or more validation sets may be temporarily extracted from the training set using methods like cross-validation (e.g., leave-one-out cross-validation, k-folds cross-validation). Evaluating the AI model consists of processing data instances of the validation set with the trained AI model to produce predictions (i.e., the configured outputs), and comparing the predictions with the associated targets. The evaluation of the validation set in Block 514 guides the hyperparameter search of Block 510. That is, the best combination of hyperparameters is selected by comparing the performance of each model, with its associated hyperparameters, as evaluated on the validation set. As stated, in some embodiments, the hyperparameter search may be performed over data sets temporarily extracted from the training set through cross-validation techniques.

Through the iterations of Block 510 and the evaluations of Block 514, the AI model with the best performing associated hyperparameters is identified. In Block 516, this AI model is selected.

In Block 520, the selected AI model is used in production. Using the AI model in production consists of making the model readily accessible to be used with new data instances not included in the set of training data. That is, the AI model may be used in the gas transmission energy management system (200).

In some implementations, before the AI model is used in production a final indication of its performance can be acquired by estimating the generalization error of the selected AI model, as shown in Block 518. The generalization error is estimated by evaluating the performance of the selected AI model on the test set. One with ordinary skill in the art will recognize that the training procedure depicted in FIG. 5 is general and that many adaptions can be made without departing from the scope of the present disclosure. For example, common training techniques, such as early stopping, adaptive or scheduled learning rates, and cross-validation may be used during training without departing from the scope of this disclosure.

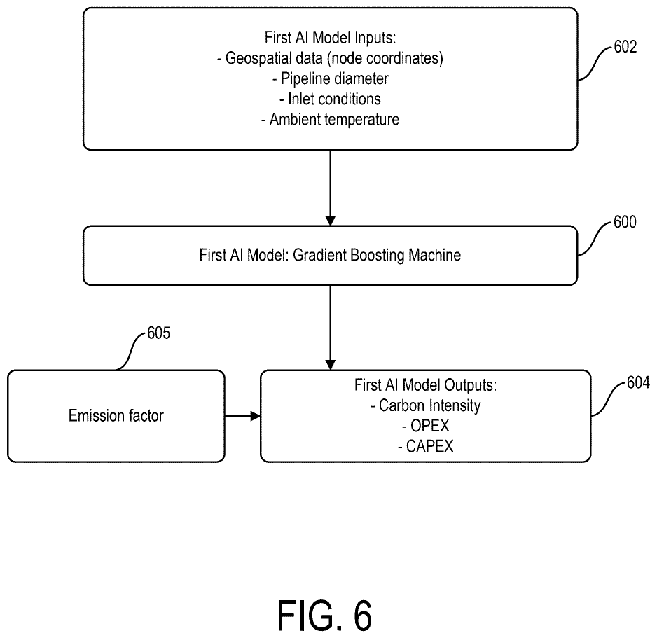

In accordance with one or more embodiments, the set of AI models (260) includes a first AI model (600) and a second AI model (700). The first AI model (600) is a gradient boosting machine (GBM) model that rapidly estimate key outputs including carbon intensity (CI), operational cost (OPEX), and capital expenditure (CAPEX) from minimal inputs such as pipeline node coordinates, pipe diameter, inlet temperature and pressure, and ambient temperature. FIG. 6 depicts the first AI model (600) operating on the first AI model inputs (602) to produce the first AI model outputs (604). In some implementations, the outputs of the first AI model (600) are further informed by a knowledge of the emission factor (605), or grid efficiency, for the country in which the gas transmission network operates. For example, a first gas transmission network and a second gas transmission network may receive electricity from different sources (e.g., electrical grid or power provider) to operate their compressor stations. Thus, the first AI model (600) may actually output a required energy consumption of the gas transmission network represented by the first AI model inputs (602) and the energy consumption can be converted to carbon intensity (CI) in view of the emission factor (605) associated with the gas transmission network according to the country in which it resides. Use of the first AI model (600), as opposed to the physics-based model (220) allows for the gas transmission energy management system to quickly produce robust and interpretable results that are particularly useful for initial feasibility analyses and strategic decision-making. That is, in one or more embodiments, the first AI model (600) acts as a surrogate model for portions of the physics-based model (220) and the surrogate model can be used, for example, with the optimizer (250) to quickly evaluate new gas transmission network designs. In other words, because the gas transmission energy management system (200) provides both a physics-based model (220) and a first AI model (650), the system offers both quick and in-depth analyses. This dual approach ensures that both preliminary assessments and advanced, granular evaluations can be conducted efficiently, making the gas transmission energy management system a versatile tool for optimizing natural gas transmission infrastructure.

A brief description of gradient boosting machines for use with the first AI model (600) is given as follows. Typically, a gradient boosting machine is an ensemble of decision trees. A decision tree is composed of nodes. A decision is made at each node such that data present at the node are segmented. Typically, at each node, the data at said node, are split into two parts, or segmented bimodally, however, multimodal segmentation is possible. The segmented data can be considered another node and may be further segmented. As such, a decision tree represents a sequence of segmentation rules. The segmentation rule (or decision) at each node is determined by an evaluation process. The evaluation process usually involves calculating which segmentation scheme results in the greatest homogeneity or reduction in variance in the segmented data. However, a detailed description of this evaluation process, or other potential segmentation scheme selection methods, is omitted for brevity and does not limit the scope of the present disclosure.

Further, if at a node in a decision tree, the data are no longer to be segmented, that node is said to be a “leaf node.” Commonly, values of data found within a leaf node are aggregated, or further modeled, such as by a linear model, so that a leaf node represents a class or has a single assigned value (e.g., an average). Thus, the leaf node has an associated assignment value. A decision tree can be configured in a variety of ways, such as, but not limited to, choosing the segmentation scheme evaluation process, limiting the number of segmentations, and limiting the number of leaf nodes. Generally, when the number of segmentations or leaf nodes in a decision tree is limited, the decision tree is said to be a “weak learner.”

In most implementations, the decision trees from which a gradient boosted machines are composed are weak learners. Additionally, for a gradient boosting machine, the decision trees are ensembled in series, wherein each decision tree makes a weighted adjustment to the output of the preceding decision trees in the series. The process of ensembling decision trees in series, and making weighted adjustments, to form a gradient boosting machine is illustrated by considering the training process of a gradient boosting machine.

The following description of the gradient boosting machine training process assumes that properly formatted training data (after normalization, imputation, etc.), which contains both the data inputs (e.g., geospatial data) and the desired output data (e.g., energy consumption), are supplied.

Training a gradient boosting machine consists of the selection of segmentation rules for each node in each decision tree; that is, training each decision tree. Once trained, a decision tree is capable of processing data. For example, a decision tree may receive a data input. The data input is sequentially transferred to nodes within the decision tree according to the segmentation rules of the decision tree. Once the data input is transferred to a leaf node, the decision tree outputs the assignment value of the associated leaf node.

Generally, training a gradient boosting machine firstly consists of making a simple prediction (SP) for the target data. The simple prediction (SP) may be the most frequent class of the target data (for categorical target data) or the average value of the target data (for numerical data). The simple prediction (SP) is subtracted from the targets to form a first residuals. The first decision tree in the series is created and trained, wherein the first decision tree attempts to predict the first residuals forming first residual predictions. The first residual predictions from the first decision tree are scaled by a scaling parameter. In the context of gradient boosting machines the scaling parameter is known as the “learning rate” (n). The learning rate is one of the hyperparameters governing the behavior of the gradient boosting machine. The learning rate (n) may be fixed for all decision trees or may be variable or adaptive. The first residual predictions of the first decision tree are multiplied by the learning rate (n) and added to the simple prediction (SP) to form a first predictions. The first predictions are subtracted from the targets to form a second residuals. A second decision tree is created and trained using the data inputs and the second residuals as targets such that it produces second residual predictions. The second residual predictions are multiplied by the learning rate (n) and are added to the first predictions forming second predictions. This process is repeated recursively until a termination criterion is achieved.

Many termination criteria exist and are not all enumerated here for brevity. Common termination criteria are terminating training when a pre-defined number of decision trees has been reached, or when improvement in the residuals is no longer observed.

Once trained, a gradient boosting machine may make predictions using input data. To do so, the input data is passed to each decision tree, which will form a plurality of residual predictions. The plurality of residual predictions are multiplied by the learning rate (n), summed across every decision tree, and added to the simple prediction (SP) formed during training to produce the gradient boosting machine prediction(s).

One with ordinary skill in the art will appreciate that many adaptions may be made to gradient boosting machines and that these adaptions do not exceed the scope of this disclosure. Some adaptions may be algorithmic optimizations, efficient handling of sparse data, use of out-of-core computing, and parallelization for distributed computing. In accordance with one or more embodiments, the first AI model (600) is an adapted gradient boosting machine model known as XGBoost.

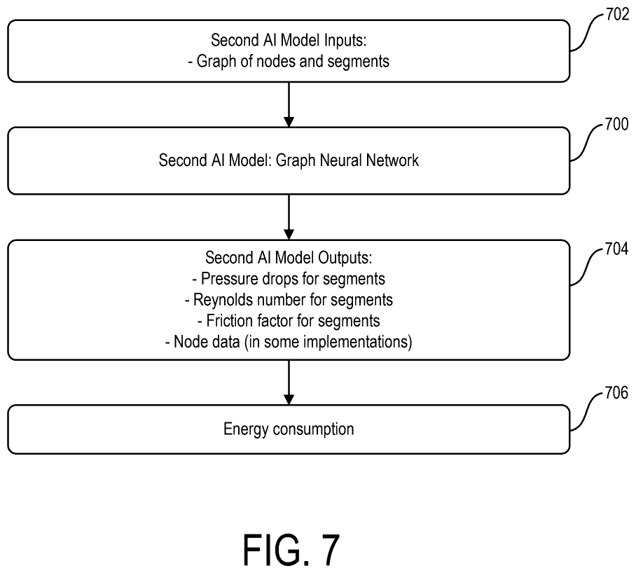

The second AI model (700) is a graph neural network (GNN) model that rapidly estimates intermediate outputs of the physics-based model (220) such as pressure drop, Reynolds number, and friction factor for segments. In some instances, the GNN further determines, or outputs, node information such as temperature and pressure for nodes that are not considered the primary inlet(s) of the gas transmission network. FIG. 7 depicts the second AI model (700) operating on the second AI model inputs (702) to produce the second AI model outputs (704). In some implementations, the outputs of the first AI model (700) are further processed, for example, using some of the equations discussed above for the physics-based model (220), to determine quantities such as energy consumption. That is, in some implementations, the second AI model (700) is used to bypass some computations of the physics-based model (220), and its outputs can be used by the remaining portion of the physics-based model (220) to achieve cost estimates. Further, use of both the physics-based model (220) and the second AI model allows the gas transmission energy management system (200) to cross-validate results, ensuring that the predictions are accurate, robust, and adaptable to various operational scenarios, thereby enhancing the overall effectiveness of the gas transmission energy management system (200).

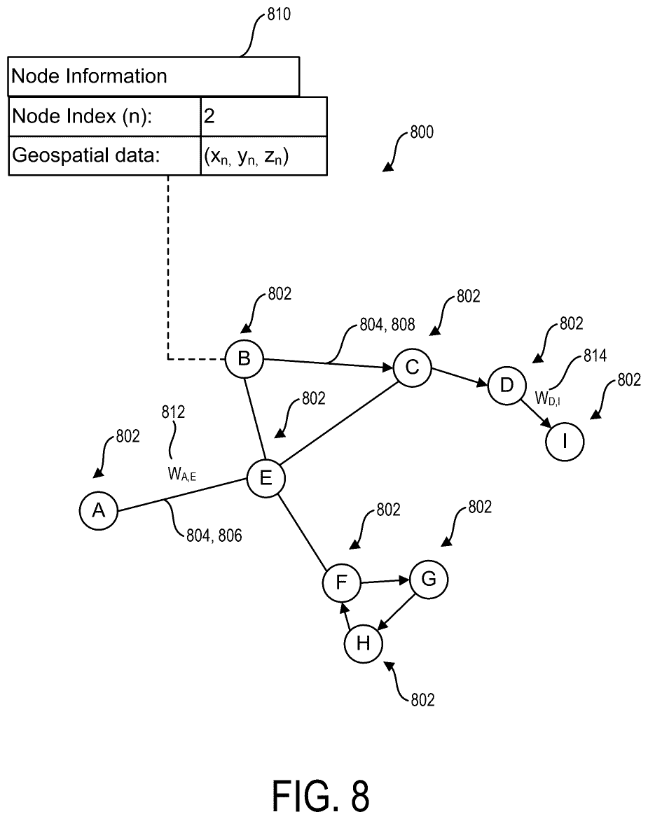

A brief description of graphs and graph neural networks (GNNs) for use with the second AI model (700) are given as follows. FIG. 8 depicts a generalized graph. In general, a graph is composed of two or more nodes (802) (or vertices), where each node (or vertex) represents an item (e.g., a sample). In FIG. 8, each node (802) is given an alphabetic identifier (i.e., “A,” “B,” “C,” etc.). A node (802) may include node information (810) describing the item it represents. For example, if a node represents an end of a segment of a gas transmission pipeline, the node may include information such as the index of the node and geospatial data (e.g., the longitude, latitude, and elevation of the node. In some implementations, the node can further contain, or be used to determine, other node information such as the temperature and pressure of the gas at the node. FIG. 8 depicts example node information (810) associated with Node B.

In a graph, relations between the nodes (802) are represented as edges (804). Edges (804) may also be referred to as lines or links. Note that to avoid unnecessarily cluttering FIG. 8, not every edge (804) is annotated with a numeric identifier. Edges (804) may further be classified as either an undirected edge (806) or a directed edge (808). When a graph is graphically depicted, directed edges (808) are typically drawn with a line terminating with an arrowhead. In contrast, undirected edges (806), when depicted graphically, do not use arrowheads. Again, to avoid cluttering FIG. 8, not every undirected edge (806) and directed edge (808) are annotated with a numeric identifier.

In general, a directed edge (808) indicates a constraint or asymmetry between the nodes (802) that it connects. For example, if each node in a graph represents an intersection of streets, then each edge may be said to represent the street, or roadway, that physically connects the two intersections. If a connecting street is a “one-way” street (i.e., a street that only allows for traffic to proceed in a single direction), then a directed edge (808) may be used to indicate that traffic can only flow in one direction, whereas an undirected edge (806) would indicate that the street it represents allows for bidirectional traffic. The example graph (800) of FIG. 8 depicts both undirected edges (806) and directed edges (808). A graph may be composed of only undirected edges (806), in which case it may be categorized as an undirected graph. Likewise, a graph may be composed of only directed edges (808) and, as such, categorized as a directed graph. Further, a directed graph may exhibit acyclic and/or cyclic behavior or connections between its nodes (802). For example, in the example graph (800), the connection between Node C proceeding to Node D and further continuing to Node I is acyclic as there is no way to return to a previous node (either Node C or Node D) upon traversing those edges (804). In contrast, Node F, Node G, and Node H demonstrate cyclic behavior because, while although their connecting edges (804) are directed edges (808), traversal of their connecting edges (804) does not prohibit access to any of those nodes (802). A directed graph with any cyclic connections may be termed a cyclic graph and a directed graph completely absent of cyclic connections is often referred to as an acyclic graph (i.e., a directed acyclic graph (DAG)).

Edges (804) of a graph, whether undirected edges (806) or directed edges (808), may be associated with an edge weight. An edge weight is typically a numeric value (i.e., a scalar), however, in some instances, an edge (804) may be associated with two or more weights in which case the edge weight may be better represented or described as a vector or tensor of any given rank. In the context of a gas transmission network represented as a graph, the edge weight can include the length of a segment between the two nodes of the edge, the ambient temperature experienced by the segment, etc. FIG. 8 depicts a first edge weight (812), W_{A,E}, associated with the edge (804) connecting Node A and Node E. Again, to avoid cluttering FIG. 8, the edge weight for every edge (804) is not depicted. However, it will be well understood by one of ordinary skill in the art that any edge (804) in a graph may be associated with an edge weight. For example, FIG. 8 depicts a second edge weight (814), W_{D,1}, associated with the directed edge (808) connecting Node D and Node I.

In general, graphs may be represented and computationally stored in a variety of different data structures. For example, graphs may be represented using an adjacency matrix, adjacency list, or adjacency set; to name a few data structures. An example adjacency list for the graph depicted in FIG. 8 is provided herein as Table IV. As seen, in an adjacency list, each node is associated with a “node list” that lists that identifies the nodes connected to the given node. For undirected edges (806), connected nodes will each occur in the node list of the non-referenced node. Node information (810) and edge weights may further be stored in a data structure representative of a graph without limitation. One with ordinary skill in the art will appreciate that the instant disclosure places no limitation on how a constructed graph may be represented and/or computationally stored.

TABLE IV
Adjacency matrix for the graph of FIG. 8. Note that
node information and edge weights are not shown as
part of the adjacency matrix but may be included.

| Node | Edges |
|---|---|
| A | [E] |
| B | [C, E] |
| C | [D, E] |
| D | [ ] |
| E | [A, B, C, F] |
| F | [E, G] |
| G | [H] |
| H | [F] |

Other methods for storing or representing a graph include the use of tables, such as the node table (320) and segment table (322) of FIG. 3.

In accordance with one or more embodiments, the gas transmission energy management system (200) leverages a gradient boosting machine (e.g., first AI model (600)), such as XGBoost, to deliver quick, robust estimates of key outputs, including emissions, carbon intensity (CI), and costs, with minimal input data. In this approach, essential features such as geospatial coordinates, pipeline diameter, inlet temperature and pressure, ambient temperature, and the electricity grid's carbon intensity are used to train the model. The gradient boosting machine is designed to learn complex nonlinear relationships from the 2.76 million data points generated through application of the physics-based model (220) to gas transmission networks currently operating around the globe; linking these minimal inputs to the desired outputs. The ensemble structure of the gradient boosting machine, which combines many decision trees, provides high accuracy and robustness while offering interpretability through feature importance metrics. This allows users to obtain reliable estimates of emissions and costs rapidly, making it particularly useful for initial feasibility analyses and decision-making in natural gas transmission networks.

In parallel, the gas transmission energy management system (200) incorporates a deep learning model using a graph neural network (e.g., second AI model (700)) to capture the intricate spatial and operational dynamics of gas transmission networks from the previously discussed 2.76 million data points. The graph neural network approach treats pipeline nodes (representing geospatial points along the network) and the connecting segments as a graph, effectively modelling the topological and terrain relationships that influence pipeline performance. By integrating physics-based constraints, the graph neural network extracts intermediate variables, such as pressure drops, energy consumption, and friction factors, that are critical for accurately computing compression needs, emissions, carbon intensity, and costs (e.g., operational cost). This physics-informed, hybrid model leverages both the structural connectivity of pipelines and real-time data, enabling it to predict intermediate parameters that can be used to refine final emissions estimates.

Using both the gradient boosting machine and graph neural network in tandem allows for cross-validation of results, ensuring that predictions are robust, accurate, and adaptable across various operational scenarios. As such, the AI models (260) of the gas transmission energy management system (200) enable users to provide only the essential inputs, such as pipeline node coordinates, pipe diameter, inlet temperature and pressure, ambient temperature, and the electricity grid's carbon intensity, to rapidly generate estimates for emissions, carbon intensity, and associated costs. Additionally, the gas transmission energy management system (200) offers the capability to perform more in-depth analyses by calculating a comprehensive range of variables throughout a gas transmission network, allowing users to gain detailed insights into operational performance and environmental impact. This dual approach ensures that both preliminary assessments and advanced, granular evaluations can be conducted efficiently, so that the gas transmission energy management system (200) can be used for optimizing natural gas transmission infrastructure (e.g., sustainability and optimized operation).

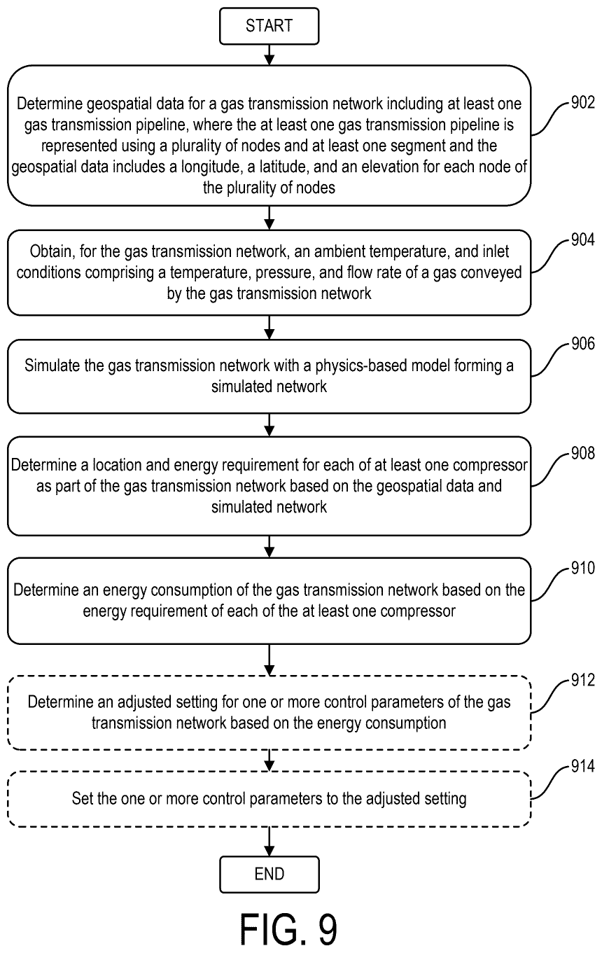

FIG. 9 depicts a method (900) in accordance with one or more embodiments. The method of FIG. 9 includes one or more steps that are performed by, or using, the gas transmission energy management system (200) as described above. While the various steps in the method (900) are presented and described sequentially, one of ordinary skill in the art will appreciate that some or all of the steps may be executed in different orders, may be combined or omitted, and some or all of the steps may be executed in parallel. Furthermore, the steps may be performed actively or passively.

Keeping with FIG. 9, Step 902 includes determining geospatial data for a gas transmission network. The gas transmission network includes at least one gas transmission pipeline. The gas transmission network is represented using a plurality of nodes and at least one segment. In one or more embodiments, a graph representation of the gas transmission network is determined, e.g., using a network transmission analysis, and used to form the geospatial data. The geospatial data includes, at least, a longitude, a latitude, and an elevation for each of the plurality of nodes.

In Step 904, an ambient temperature and inlet conditions are obtained for the gas transmission network. In some embodiments, the ambient temperature can vary spatially and/or temporally for the gas transmission network, e.g., a different ambient temperature for each segment and/or different ambient temperatures for different seasons or times of the year. The inlet conditions include an temperature, a pressure, and a flow rate of a gas conveyed by the gas transmission network at one or more inlets (or starting points) of the gas transmission network.

In Step 906, the gas transmission network is simulated using a physics-based model forming a simulated network. The physics-based model considers climate (i.e., ambient temperature), geospatial data (including changes in elevation experienced by the gas transmission network), thermodynamics, and fluid dynamics—along with default values based on literature, where needed (e.g., for heat transfer coefficients, standard pipeline thicknesses, etc.)—to determine the simulated network. The simulated network includes, at least, a calculated (i.e., determined, simulated) pressure, temperature, and flow rate at each of the plurality of nodes.

In Step 908, a location and energy requirement for each of at least one compressors (or compressor stations) is determined for the gas transmission network based on the geospatial data and the simulated network. In one or more embodiments, compressor stations are determined to be placed at fixed intervals or distances along gas transmission pipelines of the gas transmission network. The energy requirements consider the thermophysical properties of the gas at the location(s) of the at least one compressor according to the simulated network.

In Step 910, an energy consumption of the gas transmission network is determined based on the energy requirement of the at least one compressor. In some embodiments, the energy consumption of the gas transmission network is the sum of the energy requirements of its compressors. In one or more embodiments, additional costs or metrics of the gas transmission network are determined, such as emission and carbon intensity.

The method (900) of FIG. 9 also depicts Steps 912 and 914 which are considered optional or additional steps that can be implemented in accordance with one or more embodiments. In Step 912, an adjusted setting for one or more control parameters of the gas transmission network is determined based on the energy consumption. An example of a control parameter is a choke valve setting of a choke valve of the gas transmission network. In Step 914, the one or more control parameters are set to the adjusted setting. For example, a choke valve can be set to the adjusted choke valve setting using a command.

One or more embodiments disclosed herein provide several advantages described as follows. The gas transmission energy management system (200) described herein enables operators to track energy usage and estimate carbon intensity, two key metrics for assessing sustainability. Further, energy-intensive operations at compression stations can be optimized to minimize carbon footprint and energy consumption while maintaining operability. The gas transmission energy management system (200) described herein allows for regulatory compliance reporting. The gas transmission energy management system (200) generates detailed, data-driven reports on energy consumption, carbon intensity, and emissions. These reports support compliance with environmental regulations and provide transparent benchmarks for industry standards, aiding companies in meeting regulatory requirements. The gas transmission energy management system (200) further provides predictive maintenance and risk management. By leveraging real-time data and using the set of AI models (260), the gas transmission energy management system (200) can detect anomalies (e.g., anomaly detection (245) on either the model outputs (230), outputs of the set of AI models (260), or combinations thereof) and predict potential equipment failures. For example, a sudden increase in energy consumption, emissions, or carbon intensity may indicate that compressor performance is degrading, signaling the need for maintenance or system optimization (e.g., using the optimizer (250)). This allows for proactive maintenance scheduling, reducing downtime and ensuring pipeline integrity while minimizing the risk of unexpected operational disruptions. Further, the gas transmission energy management system (200) is a concrete, integrated system that combines advanced AI techniques with detailed geospatial, thermodynamic, and operational analyses to optimize natural gas pipeline networks' environmental performance. The gas transmission energy management system (200) provides tangible outputs, such as precise estimates of energy consumption, emissions, carbon intensity, and cost metrics, that directly inform infrastructure design, operational adjustments, and maintenance scheduling. By integrating real-time sensor data, historical performance metrics, and predictive analytics, the gas transmission energy management system (200) creates actionable insights that can be directly implemented in both new pipeline constructions and existing gas transmission networks. This practical application of data-driven decision-making, combined with its ability to perform scenario analysis, realize repairs and/or upgrades, adjust operational parameters, and support regulatory compliance, clearly distinguishes it from mere mathematical algorithms or business methods. Additionally, the gas transmission energy management system (200) can issue commands (e.g., Command X (270)) to gas transmission networks (or components thereof such as choke valves) to alter or adjust the operation of the gas transmission networks. That is, in one or more embodiments, operation and control of a gas transmission network is executed based on determined quantities of the gas transmission energy management system (e.g., model outputs (230)).

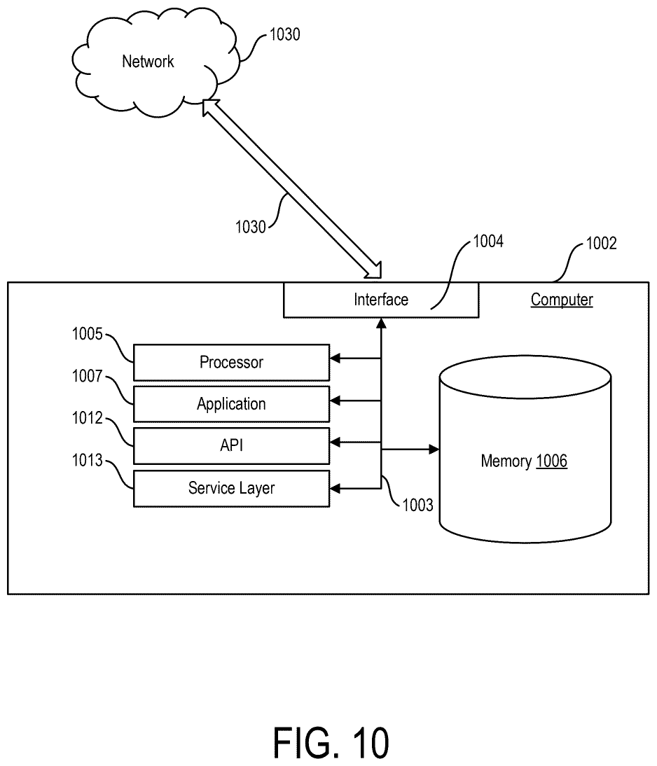

FIG. 10 further depicts a block diagram of a computer system (1002) (e.g., the pressure control system) used to provide computational functionalities associated with the methods, functions, processes, flows, and procedures as described in this disclosure, according to one or more embodiments. The illustrated computer (1002) is intended to encompass any computing device such as a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer (1002) may include a computer that includes an input device, such as a keypad, keyboard, touch screen, or other device that can accept user information, and an output device that conveys information associated with the operation of the computer (1002), including digital data, visual, or audio information (or a combination of information), or a GUI.

The computer (1002) can serve in a role as a client, network component, a server, a database or other persistency, or any other component (or a combination of roles) of a computer system for performing the subject matter described in the instant disclosure. In some implementations, one or more components of the computer (1002) may be configured to operate within environments, including cloud-computing-based, local, global, or other environment (or a combination of environments).

At a high level, the computer (1002) is an electronic computing device operable to receive, transmit, process, store, or manage data and information associated with the described subject matter. According to some implementations, the computer (1002) may also include or be communicably coupled with an application server, e-mail server, web server, caching server, streaming data server, business intelligence (BI) server, or other server (or a combination of servers).

The computer (1002) can receive requests over network (1030) from a client application (for example, executing on another computer (1002) and responding to the received requests by processing the said requests in an appropriate software application. In addition, requests may also be sent to the computer (1002) from internal users (for example, from a command console or by other appropriate access method), external or third-parties, other automated applications, as well as any other appropriate entities, individuals, systems, or computers.

Each of the components of the computer (1002) can communicate using a system bus (1003). In some implementations, any or all of the components of the computer (1002), both hardware or software (or a combination of hardware and software), may interface with each other or the interface (1004) (or a combination of both) over the system bus (1003) using an application programming interface (API) (1012) or a service layer (1013) (or a combination of the API (1012) and service layer (1013). The API (1012) may include specifications for routines, data structures, and object classes. The API (1012) may be either computer-language independent or dependent and refer to a complete interface, a single function, or even a set of APIs. The service layer (1013) provides software services to the computer (1002) or other components (whether or not illustrated) that are communicably coupled to the computer (1002). The functionality of the computer (1002) may be accessible for all service consumers using this service layer. Software services, such as those provided by the service layer (1013), provide reusable, defined business functionalities through a defined interface. For example, the interface may be software written in JAVA, C++, or other suitable language providing data in extensible markup language (XML) format or another suitable format. While illustrated as an integrated component of the computer (1002), alternative implementations may illustrate the API (1012) or the service layer (1013) as stand-alone components in relation to other components of the computer (1002) or other components (whether or not illustrated) that are communicably coupled to the computer (1002). Moreover, any or all parts of the API (1012) or the service layer (1013) may be implemented as child or sub-modules of another software module, enterprise application, or hardware module without departing from the scope of this disclosure.

The computer (1002) includes an interface (1004). Although illustrated as a single interface (1004) in FIG. 10, two or more interfaces (1004) may be used according to particular needs, desires, or particular implementations of the computer (1002). The interface (1004) is used by the computer (1002) for communicating with other systems in a distributed environment that are connected to the network (1030). Generally, the interface (1004) includes logic encoded in software or hardware (or a combination of software and hardware) and operable to communicate with the network (1030). More specifically, the interface (1004) may include software supporting one or more communication protocols associated with communications such that the network (1030) or interface's hardware is operable to communicate physical signals within and outside of the illustrated computer (1002).

The computer (1002) includes at least one computer processor (1005). Although illustrated as a single computer processor (1005) in FIG. 10, two or more processors may be used according to particular needs, desires, or particular implementations of the computer (1002). Generally, the computer processor (1005) executes instructions and manipulates data to perform the operations of the computer (1002) and any algorithms, methods, functions, processes, flows, and procedures as described in the instant disclosure.

The computer (1002) also includes a memory (1006) that holds data for the computer (1002) or other components (or a combination of both) that can be connected to the network (1030). The memory may be a non-transitory computer readable medium. For example, memory (1006) can be a database storing data consistent with this disclosure. Although illustrated as a single memory (1006) in FIG. 10, two or more memories may be used according to particular needs, desires, or particular implementations of the computer (1002) and the described functionality. While memory (1006) is illustrated as an integral component of the computer (1002), in alternative implementations, memory (1006) can be external to the computer (1002).

The application (1007) is an algorithmic software engine providing functionality according to particular needs, desires, or particular implementations of the computer (1002), particularly with respect to functionality described in this disclosure. For example, application (1007) can serve as one or more components, modules, applications, etc. Further, although illustrated as a single application (1007), the application (1007) may be implemented as multiple applications (1007) on the computer (1002). In addition, although illustrated as integral to the computer (1002), in alternative implementations, the application (1007) can be external to the computer (1002).

There may be any number of computers (1002) associated with, or external to, a computer system containing computer (1002), wherein each computer (1002) communicates over network (1030). Further, the term “client,” “user,” and other appropriate terminology may be used interchangeably as appropriate without departing from the scope of this disclosure. Moreover, this disclosure contemplates that many users may use one computer (1002), or that one user may use multiple computers (1002).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed is:

1. A method, comprising:
determining geospatial data for a gas transmission network comprising at least one gas transmission pipeline, wherein the at least one gas transmission pipeline is represented using a plurality of nodes and at least one segment and the geospatial data comprises a longitude, a latitude, and an elevation for each node of the plurality of nodes;
obtaining, for the gas transmission network, an ambient temperature, and inlet conditions comprising a temperature, pressure, and flow rate of a gas conveyed by the gas transmission network;
simulating the gas transmission network with a physics-based model forming a simulated network, comprising:
determining a length of each segment of the at least one segment using the geospatial data,
determining a change in elevation between each node of the plurality of nodes using the geospatial data, and
determining a temperature and pressure of the gas at each of the plurality of nodes based, at least in part, on the length and change in elevation of each of the at least one segments and a spatial relationship of the plurality of nodes;
determining a location and energy requirement for each of at least one compressor as part of the gas transmission network based on the geospatial data and simulated network; and
determining an energy consumption of the gas transmission network based on the energy requirement of each of the at least one compressor.

2. The method of claim 1, further comprising:
determining an adjusted setting for one or more control parameters of the gas transmission network based on the energy consumption; and
setting the one or more control parameters to the adjusted setting.

3. The method of claim 2, wherein the one or more control parameters comprise a choke valve setting for a choke valve of the gas transmission network.

4. The method of claim 2, wherein the adjusted setting, when applied to the gas transmission network, reduces the energy consumption.

5. The method of claim 1, further comprising determining a carbon intensity of the gas transmission network based on the energy consumption.

6. The method of claim 1, wherein simulating the gas transmission network further comprises:
determining a friction factor, a compressibility factor, a heat loss, and a pressure drop for each of the at least one segment,
wherein the heat loss is based, at least in part, on the ambient temperature,
wherein the pressure drop includes a pressure drop due to friction and a pressure drop due to the change in elevation.

7. The method of claim 1, further comprising determining a graph representation of the gas transmission network, wherein the geospatial data is, or is based on, the graph representation.

8. The method of claim 1, further comprising:
obtaining transmission network data comprising geospatial data for a plurality of gas transmission networks;
simulating each of the plurality of gas transmission networks with the physics-based model forming a plurality of simulated networks;
generating training data for an artificial intelligence (AI) model from the transmission network data and simulated networks of the plurality of gas transmission networks; and
training the AI model to predict an energy consumption of a given gas transmission network based on geospatial data for the given gas transmission network.

9. The method of claim 8, further comprising:
determining geospatial data for another gas transmission network; and
determining, using the AI model, an energy consumption for the another gas transmission network based on the geospatial data for the another gas transmission network.

10. The method of claim 1, further comprising designing another gas transmission network that minimizes an energy consumption of the another gas transmission network wherein the energy consumption of the another gas transmission network is determined using the physics-based model.

11. A system, comprising:
a gas transmission network comprising at least one gas transmission pipeline; and
a computer comprising at least one computer processor and configured to:
determine geospatial data for the gas transmission network, wherein the geospatial data represents the gas transmission network with a plurality of nodes and at least one segment and the geospatial data comprises a longitude, a latitude, and an elevation for each node of the plurality of nodes;
obtain, for the gas transmission network, an ambient temperature, and inlet conditions comprising a temperature, pressure, and flow rate of a gas conveyed by the gas transmission network;
simulate the gas transmission network with a physics-based model forming a simulated network, comprising:
determining a length of each segment of the at least one segment using the geospatial data;
determining a change in elevation between each node of the plurality of nodes using the geospatial data; and
determining a temperature and pressure of the gas at each of the plurality of nodes based, at least in part, on the length and change in elevation of each of the at least one segments and a spatial relationship of the plurality of nodes,
determine a location and energy requirement for each of at least one compressor as part of the gas transmission network based on the geospatial data and simulated network, and
determine an energy consumption of the gas transmission network based on the energy requirement of each of the at least one compressor.

12. The system of claim 11, wherein:
the gas transmission network further comprises one or more controllable devices controlled according to associated one or more control parameters, and
the computer is further configured to:
determine an adjusted setting for the one or more control parameters of the gas transmission network based on the energy consumption; and
setting the one or more control parameters to the adjusted setting.

13. The system of claim 12, wherein the one or more control parameters comprise a choke valve setting for a choke valve of the gas transmission network.

14. The system of claim 12, wherein the adjusted setting, when applied to the gas transmission network, reduces the energy consumption.

15. The system of claim 11, wherein the computer is further configured to determine a carbon intensity of the gas transmission network based on the energy consumption.

16. The system of claim 11, wherein simulating the gas transmission network further comprises:
determining a friction factor, compressibility factor, heat loss, and pressure drop for each of the at least one segment,
wherein the heat loss is based, at least in part, on the ambient temperature,
wherein the pressure drop includes a pressure drop due to friction and a pressure drop due to the change in elevation.

17. The system of claim 11, wherein the computer is further configured to determine a graph representation of the gas transmission network, wherein the geospatial data is, or is based on, the graph representation.

18. The system of claim 11, wherein the computer is further configured to:
obtain transmission network data comprising geospatial data for a plurality of gas transmission networks from a transmission network database;
simulate each of the plurality of gas transmission networks with the physics-based model forming a plurality of simulated networks;
generate training data for an artificial intelligence (AI) model from the transmission network data and simulated networks of the plurality of gas transmission networks; and
train the AI model to predict an energy consumption of a given gas transmission network based on geospatial data for the given gas transmission network.

19. The system of claim 18, wherein the computer is further configured to:
determine geospatial data for another gas transmission network; and
determine, using the AI model, an energy consumption for the another gas transmission network based on the geospatial data for the another gas transmission network.

20. The system of claim 11, wherein the computer is further configured to design another gas transmission network that minimizes an energy consumption of the another gas transmission network wherein the energy consumption of the another gas transmission network is determined using the physics-based model.
